(19) United States
(12) Patent Application Publication
(10) Pub. No.: US 2024/0171878 A1
(43) Pub. Date: May 23, 2024

(54) IMAGING ELEMENT, IMAGING DEVICE, AND METHOD FOR CONTROLLING IMAGING ELEMENT

(71) Applicant: SONY SEMICONDUCTOR SOLUTIONS CORPORATION, KANAGAWA (JP)

(72) Inventor: KOHEI YAMADA, KANAGAWA (JP)

(21) Appl. No.: 18/551,236

(22) PCT Filed: Feb. 2, 2022
(86) PCT No.: PCT/JP2022/003936

§ 371 Date: Sep. 19, 2023

(30) Foreign Application Priority Data
Mar. 29, 2021 (JP) 2021-055478

(51) Int. Cl. H04N 25/77; H01L 27/146; H04N 25/47; H04N 25/79

(52) U.S. Cl. CPC H04N 25/77; H01L 27/14629; H01L 27/14634; H04N 25/47; H04N 25/79

(57) ABSTRACT

An imaging element of an aspect according to the present disclosure includes a light receiving section (61) including a photoelectric conversion element that generates a charge, an event detecting section (63) that generates an event detection signal on the basis of the charge supplied from the light receiving section (61), a pixel signal generating section (62) that generates a pixel signal on the basis of the charge supplied from the light receiving section (61), and a switching transistor (253) that is an example of a single switching element that switches between a first electric path through which the charge is supplied from the light receiving section (61) to the event detecting section (63) and a second electric path through which the charge is supplied from the light receiving section (61) to the pixel signal generating section (62).

### FIELD

The present disclosure relates to an imaging element, an imaging device, and a method for controlling an imaging element.

### BACKGROUND

In recent years, there has been proposed an asynchronous imaging element (solid-state imaging element) including an event detection circuit that detects, as an event, that a light amount of a pixel exceeds a threshold value in real time. For example, in an asynchronous imaging element that performs event detection by signal difference, event detection is performed, and only signal information in which an event has occurred is updated, thereby enabling low power consumption and high speed sensing. In addition to such event detection, an imaging element capable of performing imaging has been proposed (see, for example, Patent Literature 1).

### CITATION LIST

### Patent Literature

Patent Literature 1: JP 2020-57949 A

### SUMMARY

### Technical Problem

However, in an imaging element capable of performing both event detection and imaging as described above, two transfer gates are mounted for one photodiode (PD) in order to perform both event detection and imaging. Thus, the area of the photodiode is narrowed and the use efficiency of light is lowered, and thus pixel characteristics deterioration such as deterioration of image quality and erroneous detection of an event at low illuminance occurs. Further, there is a high need for miniaturization, and as miniaturization further progresses, pixel sensitivity decreases, and thus the pixel characteristics may further deteriorate.

Therefore, the present disclosure proposes an imaging element, an imaging device, and a method for controlling the imaging element capable of suppressing deterioration of pixel characteristics.

### Solution to Problem

An imaging element according to the embodiment of the present disclosure includes: a light receiving section that includes a photoelectric conversion element that generates a charge; an event detecting section that generates an event detection signal on a basis of the charge supplied from the light receiving section; a pixel signal generating section that generates a pixel signal on a basis of the charge supplied from the light receiving section; and a switching element that switches between a first electric path through which the charge is supplied from the light receiving section to the event detecting section and a second electric path through which the charge is supplied from the light receiving section to the pixel signal generating section.

An imaging device according to the embodiment of the present disclosure includes: an imaging lens; and an imaging element, wherein the imaging element includes a light receiving section that includes a photoelectric conversion element that generates a charge, an event detecting section that generates an event detection signal on a basis of the charge supplied from the light receiving section, a pixel signal generating section that generates a pixel signal on a basis of the charge supplied from the light receiving section, and a switching element that switches between a first electric path through which the charge is supplied from the light receiving section to the event detecting section and a second electric path through which the charge is supplied from the light receiving section to the pixel signal generating section.

A method for controlling an imaging element according to the embodiment of the present disclosure, the method includes: by a switching element, switching between a first electric path through which a charge is supplied from a light receiving section including a photoelectric conversion element that generates the charge to an event detecting section that generates an event detection signal on a basis of the charge, and a second electric path through which the charge is supplied from the light receiving section to a pixel signal generating section that generates a pixel signal on a basis of the charge.

### BRIEF DESCRIPTION OF DRAWINGS

FIG. 1 is a diagram depicting an example of a schematic configuration of an imaging device according to a first embodiment.

FIG. 2 is a diagram depicting an example of a stacked structure of an imaging element according to the first embodiment.

FIG. 3 is a diagram depicting an example of a schematic configuration of the imaging element according to the first embodiment.

FIG. 4 is a diagram depicting an example of a schematic configuration of a pixel block according to the first embodiment.

FIG. 5 is a diagram depicting an example of a schematic configuration of a color filter array according to the first embodiment.

FIG. 6 is a first diagram depicting an example of a schematic configuration of a pixel circuit according to the first embodiment.

FIG. 7 is a second diagram depicting an example of a schematic configuration of the pixel circuit according to the first embodiment.

FIG. 8 is a diagram depicting an example of a schematic configuration of a pixel according to the first embodiment.

FIG. 9 is a first diagram depicting an example of a schematic configuration of an operation of the imaging element according to the first embodiment.

FIG. 10 is a second diagram depicting an example of a schematic configuration of the operation of the imaging element according to the first embodiment.

FIG. 11 is a third diagram depicting an example of a schematic configuration of the operation of the imaging element according to the first embodiment.

FIG. 12 is a fourth diagram depicting an example of a schematic configuration of the operation of the imaging element according to the first embodiment.

FIG. 13 is a diagram depicting an example of a schematic configuration of a pixel circuit according to a second embodiment.

FIG. 14 is a diagram depicting an example of a schematic configuration of a pixel circuit according to a third embodiment.

FIG. 15 is a diagram depicting an example of a schematic configuration of a pixel circuit according to a fourth embodiment.

FIG. 16 is a diagram depicting an example of a schematic configuration of a pixel circuit according to a fifth embodiment.

FIG. 17 is a diagram depicting an example of a schematic configuration of a pixel circuit according to a sixth embodiment.

FIG. 18 is a first diagram depicting an example of a schematic configuration of a pixel according to a seventh embodiment.

FIG. 19 is a second diagram (cross-sectional view taken along line B1-B1 in FIG. 18) depicting an example of a schematic configuration of the pixel according to the seventh embodiment.

FIG. 20 is a diagram depicting an example of a schematic configuration of the pixel according to the seventh embodiment.

FIG. 21 is a block diagram depicting an example of schematic configuration of a vehicle control system.

FIG. 22 is a diagram of assistance in explaining an example of installation positions of an outside-vehicle information detecting section and an imaging section.

### DESCRIPTION OF EMBODIMENTS

Hereinafter, embodiments of the present disclosure will be described in detail with reference to the drawings. Note that the elements, apparatuses, methods, and the like according to the present disclosure are not limited by these embodiments. Further, in each of the following embodiments, basically the same parts are denoted by the same reference signs, and redundant description is omitted.

One or more embodiments (examples and modifications) described below can each be implemented independently. On the other hand, at least some of the plurality of embodiments described below may be appropriately combined with at least some of other embodiments. The plurality of embodiments may include novel features different from each other. Therefore, the plurality of embodiments can contribute to solving different objects or problems, and can exhibit different effects.

The present disclosure will be described according to the following order of items.
1. First Embodiment
1-1. Example of Schematic Configuration of Imaging Device
1-2. Example of Schematic Configuration of Imaging Element
1-3. Example of Schematic Configuration of Pixel Block
1-4. Example of Schematic Configuration of Color Filter Array
1-5. Example of Schematic Configuration of Pixel Circuit
1-6. Example of Schematic Configuration of Pixel
1-7. Example of Operation of Imaging Element
1-8. Effects
2. Second embodiment
2-1. Example of Schematic Configuration of Pixel Circuit
2-2. Effects
3. Third embodiment
3-1. Example of Schematic Configuration of Pixel Circuit
3-2. Effects
4. Fourth embodiment
4-1. Example of Schematic Configuration of Pixel Circuit
4-2. Effects
5. Fifth Embodiment
5-1. Example of Schematic Configuration of Pixel Circuit
5-2. Effects
6. Sixth Embodiment
6-1. Example of Schematic Configuration of Pixel
6-2. Effects
7. Seventh embodiment
7-1. Example of Schematic Configuration of Pixel
7-2. Effects
8. Eighth Embodiment
8-1. Example of Schematic Configuration of Pixel
8-2. Effects
9. Other Embodiments
10. Application Example
11. Appendix

### 1. First Embodiment

### 1-1. Example of Schematic Configuration of Imaging Device

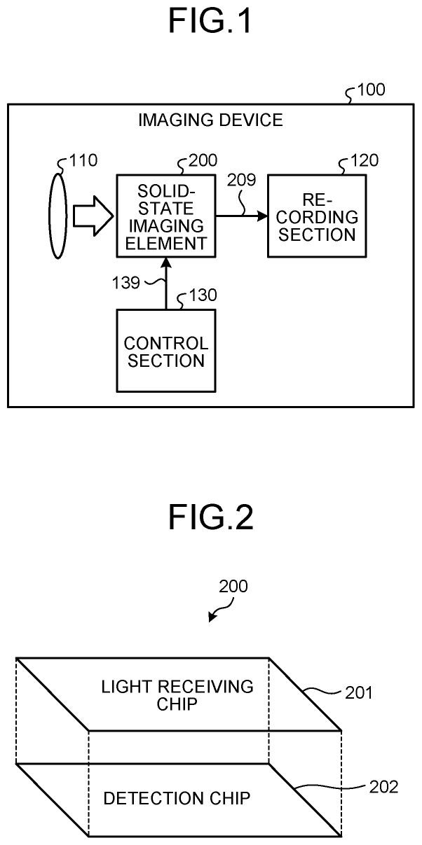

An example of a schematic configuration of an imaging device 100 according to the present embodiment will be described with reference to FIG. 1. FIG. 1 is a diagram depicting an example of a schematic configuration of an imaging device 100 according to the present embodiment.

As depicted in FIG. 1, the imaging device 100 includes an imaging lens 110, an imaging element (solid-state imaging element) 200, a recording section 120, and a control section 130. Examples of the imaging device 100 include a camera mounted on a wearable device, an industrial robot, or the like, and an in-vehicle camera mounted on a vehicle or the like.

The imaging lens 110 condenses incident light and guides the light to the imaging element 200. For example, the imaging lens 110 captures incident light from a subject and forms an image on an imaging surface (light receiving surface) of the imaging element 200.

The imaging element 200 photoelectrically converts the incident light to detect the presence or absence of an event (address event), and generates a detection result. For example, the imaging element 200 detects, as an event, that the absolute value of the change amount of the luminance has exceeded the threshold value for each of the plurality of pixels. The imaging element 200 is also referred to as an event-based vision sensor (EVS).

Here, for example, the event includes an on event and an off event, and the detection result includes a detection result of a one-bit on event and a detection result of a one-bit off event. The on event means, for example, that the amount of change in the light amount of the incident light (the amount of increase in luminance) exceeds a predetermined upper limit threshold value. On the other hand, the off-event means, for example, that the amount of change in the light amount of the incident light (the amount of decrease in luminance) has fallen below a predetermined lower limit threshold value (a value less than the upper limit threshold value).

For example, the imaging element 200 processes a detection result of an event (address event) and outputs data indicating a processing result thereof to the recording section 120 via a signal line 209. For example, the imaging element 200 generates a detection signal (event detection signal) indicating a detection result of an event for each pixel. Each detection signal includes an on-event detection signal indicating the presence or absence of an on-event and an off-event detection signal indicating the presence or absence of an off-event. Note that the imaging element 200 may detect only one of the on-event detection signal and the off-event detection signal.

Furthermore, for example, the imaging element 200 executes predetermined signal processing such as image recognition processing on image data including the detection signal, and outputs the processed data to the recording section 120 via the signal line 209.

The recording section 120 records data input from the imaging element 200. As the recording section 120, for example, a storage such as a flash memory, a dynamic random access memory (DRAM), or a static random access memory (SRAM) is used.

The control section 130 controls each section of the imaging device 100 by outputting various instructions to the imaging element 200 via a signal line 139. For example, the control section 130 controls the imaging element 200 and causes the imaging element 200 to detect the presence or absence of an event (address event). As the control section 130, for example, a computer such as a central processing unit (CPU) or a micro control unit (MPU) is used.

### 1-2. Example of Schematic Configuration of Imaging Element

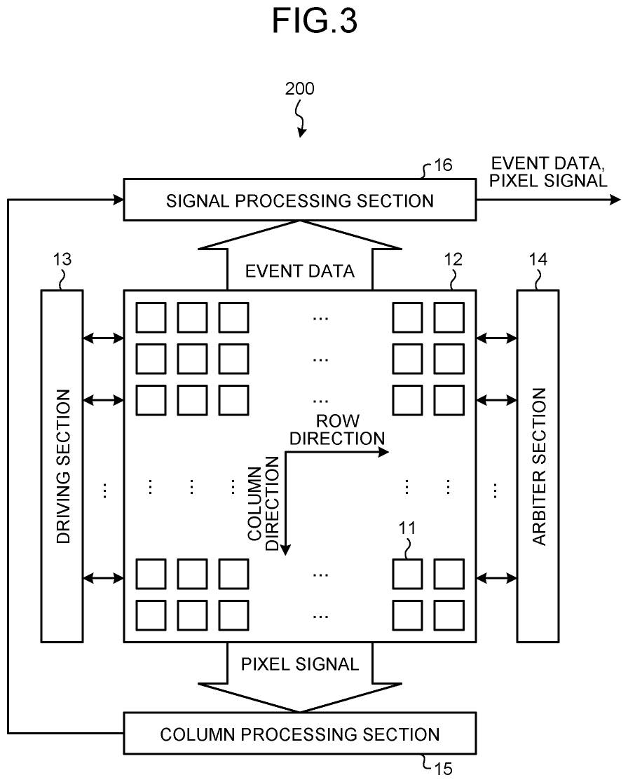

An example of a schematic configuration of the imaging element 200 according to the present embodiment will be described with reference to FIGS. 2 and 3. FIG. 2 is a diagram depicting an example of a stacked structure of the imaging element 200 according to the present embodiment. FIG. 3 is a diagram depicting an example of a schematic configuration of the imaging element 200 according to the present embodiment.

As depicted in FIG. 2, the imaging element 200 includes a light receiving chip (light receiving substrate) 201 and a detection chip (detection substrate) 202. The light receiving chip 201 is stacked on the detection chip 202. The light receiving chip 201 corresponds to a first chip (first substrate), and the detection chip 202 corresponds to a second chip (first substrate). For example, a light receiving element (for example, a photoelectric conversion element such as a photodiode) is disposed on the light receiving chip 201, and a circuit is disposed on the detection chip 202. The light receiving chip 201 and the detection chip 202 are electrically connected via a connection portion such as a via, Cu—Cu bonding, or a bump.

As depicted in FIG. 3, the imaging element 200 includes a pixel array section 12, a driving section 13, an arbiter section (arbitration section) 14, a column processing section 15, and a signal processing section 16. The driving section 13, the arbiter section 14, the column processing section 15, and the signal processing section 16 are provided as peripheral circuit sections of the pixel array section 12.

The pixel array section 12 includes a plurality of pixels (unit pixels) 11. These pixels 11 are two-dimensionally arranged in an array, for example, a matrix. A pixel address indicating the position of each pixel 11 is defined by a row address and a column address on the basis of the matrix arrangement of the pixels 11. Each of the pixels 11 generates, as a pixel signal, an analog signal of a voltage corresponding to a photoelectric current as an electric signal generated by photoelectric conversion. Furthermore, each of the pixels 11 detects the presence or absence of an event on the basis of whether or not a change exceeding a predetermined threshold value has occurred in the photoelectric current corresponding to the luminance of the incident light. In other words, each of the pixels 11 detects that the luminance change exceeds the predetermined threshold value as an event.

Upon detecting an event, each of the pixels 11 outputs a request for requesting output of event data indicating the occurrence of the event to the arbiter section 14. Then, each of the pixels 11 outputs the event data to the driving section 13 and the signal processing section 16 when receiving a response indicating permission for output of the event data from the arbiter section 14. Furthermore, the pixel 11 that has detected the event outputs an analog pixel signal generated by photoelectric conversion to the column processing section 15.

The driving section 13 drives each pixel 11 of the pixel array section 12. For example, the driving section 13 detects an event, drives the pixel 11 that has output the event data, and outputs an analog pixel signal of the pixel 11 to the column processing section 15.

The arbiter section 14 arbitrates a request for requesting output of the event data supplied from each of the plurality of pixels 11, and transmits a response based on an arbitration result thereof (permission/non-permission of output of the event data) and a reset signal for resetting the event detection to the pixels 11.

For each pixel column of the pixel array section 12, the column processing section 15 performs processing of converting an analog pixel signal output from the pixel 11 of the column into a digital signal. For example, the column processing section 15 can also perform correlated double sampling (CDS) processing on the digitized pixel signal. The column processing section 15 includes, for example, an analog-digital conversion section including a set of analog-digital converters provided for each pixel column of the pixel array section 12. As the analog-digital converter, for example, a single-slope analog-digital converter can be exemplified.

The signal processing section 16 performs predetermined signal processing on the digitized pixel signal supplied from the column processing section 15 and the event data output from the pixel array section 12, and outputs the event data and the pixel signal after the signal processing.

Here, the change in the photoelectric current generated in the pixel 11 is regarded as a light amount change (luminance change) of light incident on the pixel 11. Therefore, it can be said that the occurrence of an event is a light amount change (luminance change) of the pixel 11 exceeding the predetermined threshold value. Note that the event data indicating the occurrence of an event includes, for example, position information such as coordinates indicating the position of the pixel 11 where a light amount change as an event has occurred. The event data can include polarity of light amount change in addition to the position information.

### 1-3. Example of Schematic Configuration of Pixel Block

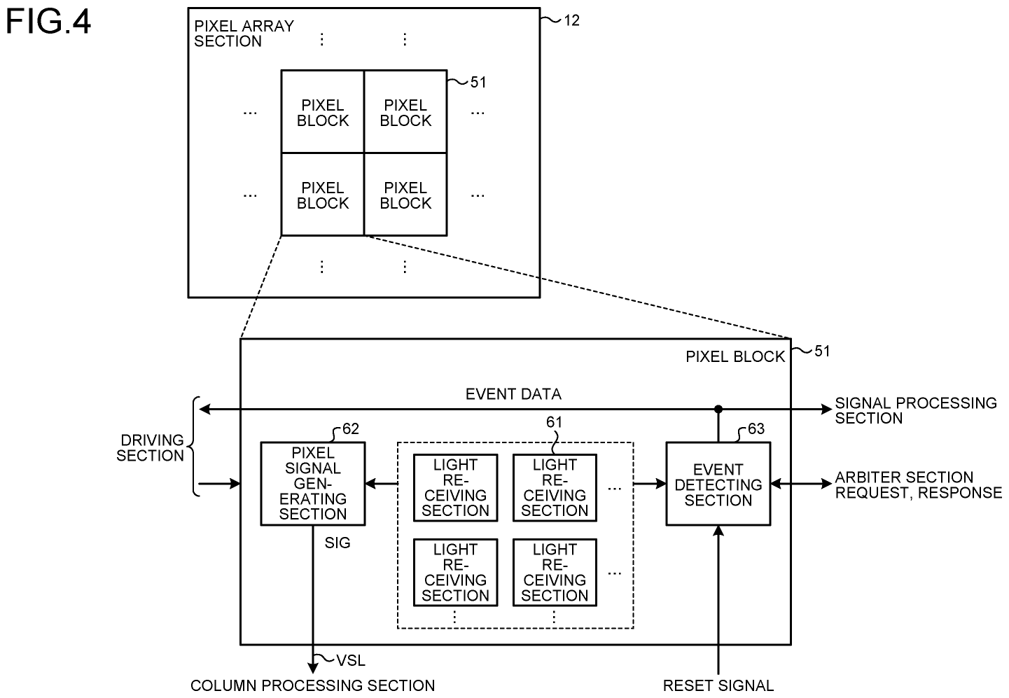

An example of a schematic configuration of a pixel block 51 according to the present embodiment will be described with reference to FIG. 4. FIG. 4 is a diagram depicting an example of a schematic configuration of the pixel block 51 according to the present embodiment.

As depicted in FIG. 4, each pixel 11 is grouped into a plurality of pixel blocks 51. Each pixel block 51 includes, for example, pixels arranged in I rows×J columns (I and J are positive integers).

Each pixel block 51 includes a plurality of light receiving sections 61, a pixel signal generating section 62, and an event detecting section 63. The light receiving sections 61 are arranged in, for example, I rows×J columns. The pixel signal generating section 62 and the event detecting section 63 are shared by the respective light receiving sections 61 in the pixel block 51. Note that the coordinates of the pixels 11 follow, for example, the coordinates of the light receiving sections 61 arranged in a two-dimensional lattice pattern.

The light receiving sections 61 photoelectrically convert the incident light to generate a photoelectric current. Then, under the control of the driving section 13 (see FIG. 3), the light receiving sections 61 each supply a signal of a voltage corresponding to the photoelectric current generated by photoelectrically converting the incident light to either the pixel signal generating section 62 or the event detecting section 63.

The pixel signal generating section 62 generates a signal of a voltage corresponding to the photoelectric current supplied from the light receiving section 61 as an analog pixel signal SIG. Then, the pixel signal generating section 62 supplies the generated analog pixel signal SIG to the column processing section 15 (see FIG. 3) via a vertical signal line VSL wired for each pixel column of the pixel array section 12.

The event detecting section 63 detects the presence or absence of occurrence of an event on the basis of whether or not the change amount of the photoelectric current supplied from each light receiving section 61 in the same pixel block 51 has exceeded a predetermined threshold value. The event includes, for example, an on-event indicating that the change amount of the photoelectric current exceeds the upper limit threshold value and an off-event indicating that the change amount falls below the lower limit threshold value. Further, the event data indicating the occurrence of an event includes, for example, one bit indicating a detection result of an on-event and one bit indicating a detection result of an off-event. Note that the event detecting section 63 can be configured to detect only an on-event.

When an event occurs, the event detecting section 63 outputs a request for requesting output of event data indicating the occurrence of the event to the arbiter section 14 (see FIG. 3). Then, in a case of receiving a response to the request from the arbiter section 14, the event detecting section 63 outputs event data (event detection signal) to the driving section 13 and the signal processing section 16.

For example, when receiving the output event data, the driving section 13 executes reading for each light receiving section 61 belonging to the pixel block 51 including the event detecting section 63 that has output the event data. By this reading, the analog pixel signal SIG is sequentially input from each light receiving section 61 belonging to the pixel block 51 as a reading target to the column processing section 15 (see FIG. 3).

Note that the pixel signal generating section 62 and the event detecting section 63 are provided for each pixel block 51, but are not limited thereto. For example, only one of the pixel signal generating section 62 and the event detecting section 63 may be provided for each pixel block 51, or both or one of the pixel signal generating section 62 and the event detecting section 63 may be provided for each light receiving section 61, that is, for each pixel 11.

### 1-4. Example of Schematic Configuration of Color Filter Array

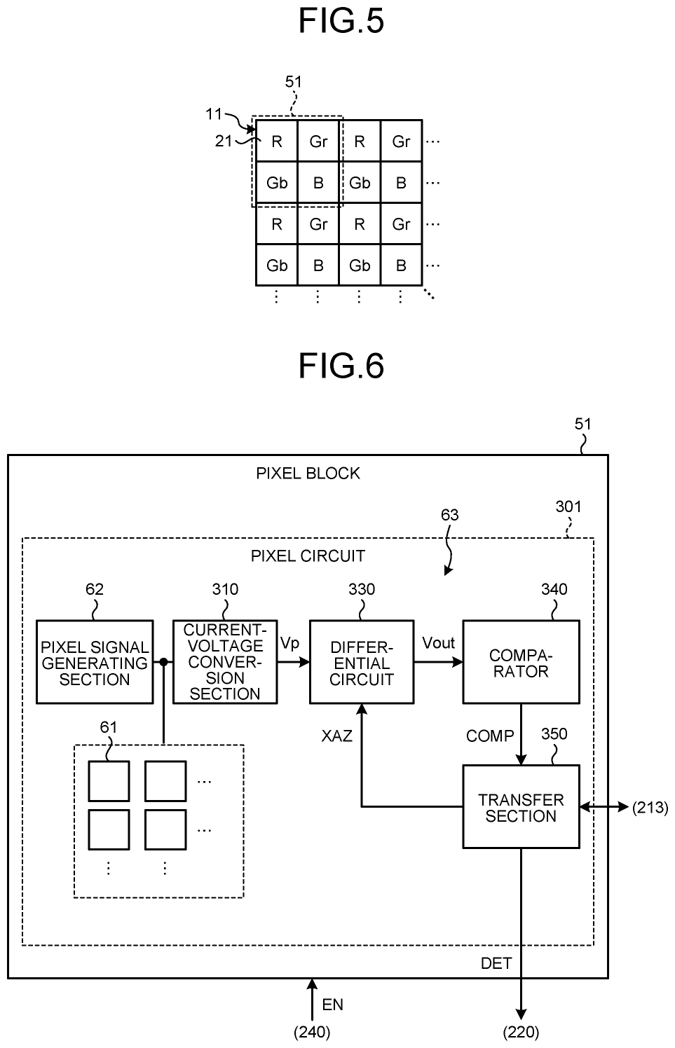

An example of a schematic configuration of a color filter array according to the present embodiment will be described with reference to FIG. 5. FIG. 5 is a diagram depicting an example of a schematic configuration of a color filter array according to the present embodiment.

The pixel block 51 includes, for example, a combination of pixels 11 that receive a wavelength component necessary for reconstructing color. For example, in a case where the color is reconfigured on the basis of three primary colors of RGB, the pixel block 51 includes a combination of a pixel 11 that receives red light, a pixel 11 that receives green light, and a pixel 11 that receives blue light. That is, the pixel block 51 is a unit of a color filter array and includes a combination of pixels (unit pixels) that receive a predetermined wavelength component.

Examples of the color filter array include various arrays such as a Bayer array of 2×2 pixels (see FIG. 5), a quad Bayer array of 4×4 pixels (also referred to as a quadra array), and a quad Bayer array of 8×8 pixels. Note that 2×2 pixels, 4×4 pixels, 8×8 pixels, and the like as the basic pattern are examples, and the number of pixels of the basic pattern is not limited. Hereinafter, a Bayer array of 2×2 pixels will be described as a representative color filter array.

### Bayer array of 2×2 pixels

As depicted in FIG. 5, in a case where the Bayer array of 2×2 pixels is employed as the color filter array, one pixel block 51 is configured by a basic pattern (unit pattern) having a total of four unit pixels of 2×2 pixels which are repeating units in the Bayer array. In the example of FIG. 5, the pixel block 51 includes, for example, one pixel 11 including a red (R) color filter 21, one pixel 11 including a green (Gr) color filter 21, one pixel 11 including a green (Gb) color filter 21, and one pixel 11 including a blue (B) color filter 21.

As described above, in the imaging element 200, the color filter 21 is provided for each pixel 11. The imaging element 200 performs event detection in a specific wavelength band based on the color filter 21. Thus, information of various wavelength bands can be detected as an event.

The color filter 21 is an example of an optical filter (wavelength selection element) that transmits predetermined light. By providing the color filter 21 in the pixel 11, any light can be received as incident light. For example, in a case where visible light is received as incident light in the pixel 11, the event data represents occurrence of a change in a pixel value in an image in which a visible subject appears. Further, for example, in a case where the pixel 11 receives infrared rays, millimeter waves, or the like for distance measurement as incident light, the event data indicates occurrence of a change in the distance to the subject. Furthermore, for example, in a case where infrared rays for measuring the temperature are received as incident light in the pixel 11, the event data indicates occurrence of a change in the temperature of the subject.

Here, for example, during traveling of the vehicle or the like, information of various wavelength bands, such as lighting (blinking) of a brake lamp or a tail lamp of the vehicle traveling in front of the host vehicle, blinking of a direction indicator, color change of a traffic light, and an electric sign, particularly information of a red (R) wavelength band (brake lamp, tail lamp, red traffic light, or the like) flies into the eyes of the driver. Basically, the driver visually detects these various types of information and determines the content of the information, but it is quite convenient if the imaging element 200 can detect and determine the information similarly to the driver.

Accordingly, in the imaging device 100 according to the present embodiment, the color filter 21, which is an example of the wavelength selection element, is provided for each pixel 11 in the imaging element 200, and threshold value detection in each pixel 11 is performed, thereby enabling event detection for each color. For example, a motion of an object detected as an event for each color is detected. Thus, an event signal for each color in each wavelength band can be used to turn on (blink) a brake lamp or a tail lamp of the vehicle, blink a direction indicator, change the color of a traffic light, and detect (sense) an electric sign or the like.

Note that, as the color filter array, for example, an RCCC filter in which red (R) pixels and clear (C) pixels are combined, an RCCB filter in which blue (B) pixels are combined with R pixels and C pixels, or an RGB Bayer array filter in which R pixels, G (green) pixels, and B pixels are combined may be used. The C pixel is a pixel not provided with a color filter or provided with a transparent filter, and is a pixel similar to the W (white) pixel. For example, the RCCC filter in which R (red) pixels and C (clear) pixels are combined can achieve high sensitivity capable of capturing images of distant obstacles, people, and the like even at low illuminance corresponding to night of moonlight. In addition, the RCCC filter can improve detection accuracy of light in the red wavelength band (for example, a tail lamp, a red light of a traffic light, or the like), which is important in in-vehicle sensing and the like, for example.

### 1-5. Example of Schematic Configuration of Pixel Circuit

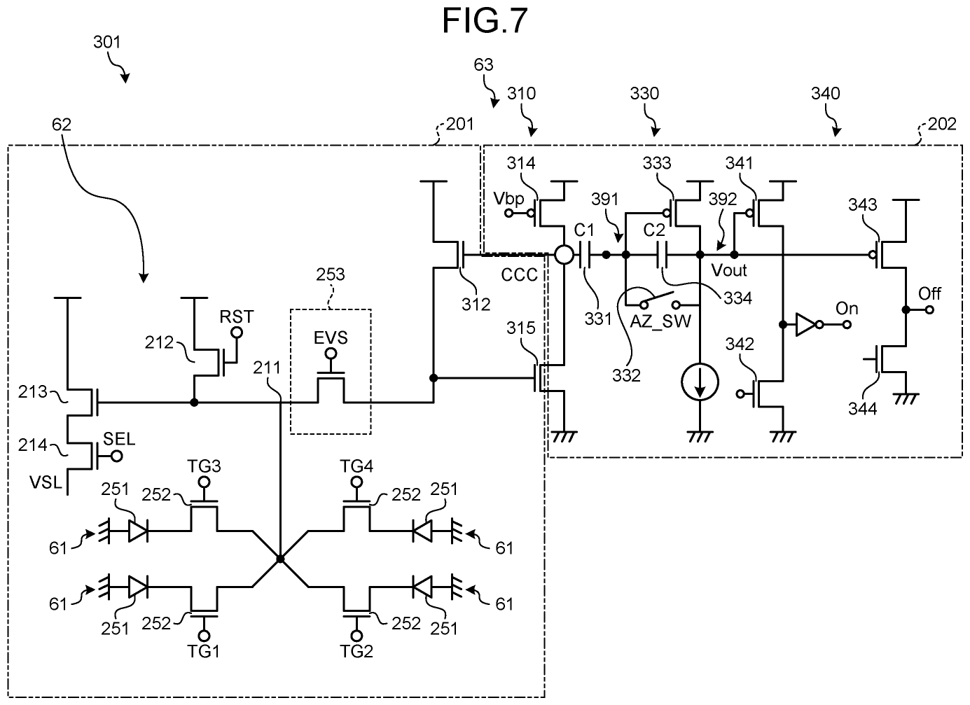

An example of a schematic configuration of a pixel circuit 301 according to the present embodiment will be described with reference to FIGS. 6 and 7. FIGS. 6 and 7 are diagrams each depicting an example of a schematic configuration of the pixel circuit 301 according to the present embodiment.

As depicted in FIG. 6, the pixel circuit 301 includes the plurality of light receiving sections 61, the pixel signal generating section 62, and the event detecting section 63. The event detecting section 63 includes a current-voltage conversion section 310, a differential circuit 330, a comparator 340, and a transfer section 350.

The current-voltage conversion section 310 converts the photoelectric current into a pixel voltage Vp proportional to the logarithmic value of the photoelectric current. The current-voltage conversion section 310 supplies the pixel voltage Vp to the differential circuit 330.

The differential circuit 330 obtains a change amount of the pixel voltage Vp by differential operation. The change amount of the pixel voltage Vp indicates the change amount of the light amount. The differential circuit 330 supplies a differential signal Vout indicating the amount of change in the light amount to the comparator 340.

The comparator 340 compares the differential signal Vout with a predetermined threshold value (upper limit threshold value or lower limit threshold value). A comparison result COMP of the comparator 340 indicates a detection result of an event (address event). The comparator 340 supplies the comparison result COMP to the transfer section 350.

The transfer section 350 transfers a detection signal DET, and supplies an auto zero signal XAZ to the differential circuit 330 to initialize the auto zero signal XAZ after the transfer. When an event is detected, the transfer section 350 supplies a request for requesting transfer of the detection signal DET to the arbiter section 14. Then, upon receiving a response to the request, the transfer section 350 supplies the comparison result COMP to a signal processing section 220 as the detection signal DET, and supplies the auto zero signal XAZ to the differential circuit 330.

Note that the event detecting section 63 may have a buffer between the current-voltage conversion section 310 and the differential circuit 330. The buffer outputs the pixel voltage Vp from the current-voltage conversion section 310 to the differential circuit 330. With this buffer, the driving force for driving a subsequent stage can be improved. In addition, the buffer can ensure isolation of noise associated with a switching operation in the subsequent stage.

As depicted in FIG. 7, the light receiving sections 61 each include a photoelectric conversion element 251 and a transfer transistor 252. In the example of FIG. 7, four light receiving sections 61 are provided. These light receiving sections 61 are connected to the pixel signal generating section 62 and the event detecting section 63. A switching transistor 253 is provided between each light receiving section 61 and the event detecting section 63. The switching transistor 253 corresponds to a switching element.

The photoelectric conversion element 251 generates a photoelectric current by photoelectric conversion with respect to incident light. As the photoelectric conversion element 251, for example, a photodiode (FD) is used. A transfer signal TG (for example, TG1, TG2, TG3, and TG4) is supplied from the driving section 13 to a gate of the transfer transistor 252. Further, a transfer signal (control signal) EVS is supplied from the driving section 13 to a gate of the switching transistor 253. Note that a source of the switching transistor 253 is connected to a floating diffusion layer 211, and a drain thereof is connected to an input terminal of the event detecting section 63.

The transfer transistor 252 transfers a charge from the corresponding photoelectric conversion element 251 to the pixel signal generating section 62 depending on the transfer signal TG from the driving section 13. Further, the transfer transistor 252 and the switching transistor 253 supply a charge (photoelectric current due to the charge), that is, an electric signal generated by the photoelectric conversion element 251 from the corresponding photoelectric conversion element 251 to the event detecting section 63 depending on the transfer signal TG and the transfer signal EVS from the driving section 13. Note that, in response to an instruction to start detection of an event, the driving section 13 drives the switching transistor 253 by the transfer signal EVS, and makes it possible to supply an electric signal from each light receiving section 61 to the event detecting section 63.

The pixel signal generating section 62 includes the floating diffusion layer 211, a reset transistor 212, an amplification transistor 213, and a selection transistor 214. As the reset transistor 212, the amplification transistor 213, and the selection transistor 214, for example, metal-oxide-semiconductor (MOS) transistors are used.

The floating diffusion layer 211 accumulates the charge transferred as a photoelectric current from the photoelectric conversion element 251 via the transfer transistor 252, and generates a voltage corresponding to the amount of the accumulated charge. The floating diffusion layer 211 may be provided for each light receiving section 61 or may be provided in common for respective light receiving sections 61.

The reset transistor 212 discharges (initializes) the charge accumulated in the floating diffusion layer 211 in accordance with a reset signal RST from the driving section 13. A source of the reset transistor 212 is connected to the floating diffusion layer 211, and a drain thereof is connected to a power supply terminal. The reset signal RST is supplied to a gate of the reset transistor 212. The reset transistor 212 corresponds to a reset element.

The amplification transistor 213 amplifies the voltage of the floating diffusion layer 211. A gate of the amplification transistor 213 is connected to the floating diffusion layer 211. A drain of the amplification transistor 213 is connected to the power supply terminal, and a source thereof is connected to a drain of the selection transistor 214.

In accordance with a selection signal SEL from the driving section 13, the selection transistor 214 outputs a signal of the voltage amplified by the amplification transistor 213 to the column processing section 15 via the vertical signal line VSL as a pixel signal SIG. A source of the selection transistor 214 is connected to the vertical signal line (VSL). The selection signal SEL is supplied to a gate of the selection transistor 214.

The current-voltage conversion section 310 includes an N-type transistor 312, a P-type transistor 314, and an N-type transistor 315. The current-voltage conversion section 310 logarithmically converts the photoelectric current into the pixel voltage Vp. As the N-type transistor 312, the P-type transistor 314, and the N-type transistor 315, for example, MOS transistors are used.

A source of the N-type transistor 312 is connected to the floating diffusion layer 211 via the switching transistor 253, and a drain thereof is connected to the power supply terminal. The P-type transistor 314 and the N-type transistor 315 are connected in series between the power supply terminal and a reference terminal of a predetermined reference potential (ground potential or the like). Further, a connection point of the P-type transistor 314 and the N-type transistor 315 is connected to a gate of the N-type transistor 312 and an input terminal of the differential circuit 330. A connection point of the source of the N-type transistor 312 and the drain of the switching transistor 253 is connected to a gate of the N-type transistor 315. Thus, the N-type transistor 312 and the N-type transistor 315 are connected in a loop. Further, a predetermined bias voltage Vbp is applied to a gate of the P-type transistor 314.

The differential circuit 330 includes a capacitor 331, a switch 332, a P-type transistor 333, and a capacitor 334. As the P-type transistor 333, for example, a MOS transistor is used.

The P-type transistor 333 is connected between the power supply terminal and the reference terminal of the predetermined reference potential. The P-type transistor 333 functions as an inversion circuit in which a gate of the P-type transistor 333 serves as an input terminal 391, and a source of the P-type transistor 333 serves as an output terminal 392.

The capacitor 331 is inserted between the current-voltage conversion section 310 and the input terminal 391. The capacitor 331 supplies a current corresponding to a time differential (in other words, the amount of change) of the pixel voltage Vp from the current-voltage conversion section 310 to the input terminal 391. In addition, the capacitor 334 is inserted between the input terminal 391 and the output terminal 392.

The switch 332 opens and closes a path between the input terminal 391 and the output terminal 392 in accordance with the auto zero signal XAZ from the transfer section 350. For example, when the low-level auto zero signal XAZ is input, the switch 332 shifts to an on state according to the auto zero signal XAZ, and sets the differential signal Vout to an initial value.

The comparator 340 includes a P-type transistor 341, an N-type transistor 342, a P-type transistor 343, and an N-type transistor 344. As the P-type transistor 341, the N-type transistor 342, the P-type transistor 343, and the N-type transistor 344, for example, MOS transistors are used.

The P-type transistor 341 and the N-type transistor 342 are connected in series between the power supply terminal and the reference terminal, and the P-type transistor 343 and the N-type transistor 344 are also connected in series between the power supply terminal and the reference terminal. Gates of the P-type transistor 341 and the P-type transistor 343 are connected to the differential circuit 330. An upper limit voltage Vhigh indicating an upper limit threshold value is applied to the gate of the N-type transistor 342, and a lower limit voltage Vlow indicating a lower limit threshold value is applied to the gate of the N-type transistor 344.

A connection point of the P-type transistor 341 and the N-type transistor 342 is connected to the transfer section 350 (see FIG. 5), and the voltage at this connection point is output as a comparison result COMP+ with the upper limit threshold value. A connection point of the P-type transistor 343 and the N-type transistor 344 is also connected to the transfer section 350, and the voltage at this connection point is output as a comparison result COMP- with the lower limit threshold value. With such a connection, the comparator 340 outputs the high-level comparison result COMP+ when the differential signal Vout is higher than the upper limit voltage Vhigh, and outputs the low-level comparison result COMP− when the differential signal Vout is lower than the lower limit voltage Vlow. The comparison result COMP is a signal including these comparison results COMP+ and COMP−.

Note that the comparator 340 compares both the upper limit threshold value and the lower limit threshold value with the differential signal Vout, but may compare only one of them with the differential signal Vout. In this case, unnecessary transistors can be reduced. For example, only the P-type transistor 341 and the N-type transistor 342 are disposed when only comparison with the upper limit threshold value is performed. In addition, although the capacitor 334 is disposed in the differential circuit 330, the capacitor 334 may be reduced.

Here, each photoelectric conversion element 251, each

transfer transistor 252, and the pixel signal generating section 62 are arranged on the light receiving chip 201. Further, a part of the current-voltage conversion section 310 (the N-type transistor 312 and the N-type transistor 315) is arranged on the light receiving chip 201. On the other hand, a part of the current-voltage conversion section 310 (the P-type transistor 314) , the differential circuit 330, the comparator 340, and the transfer section 350 are arranged on the detection chip 202. Note that the respective circuits and elements arranged in the light receiving chip 201 and the detection chip 202 are not limited to this configuration.

In addition, the light receiving chip 201 and the detection chip 202 are bonded by Cu—Cu bonding (CCC). The position of the Cu-Cu bonding is, for example, a node of the P-type transistor 314, but is not limited to the position.

### 1-6. Example of Schematic Configuration of Pixel

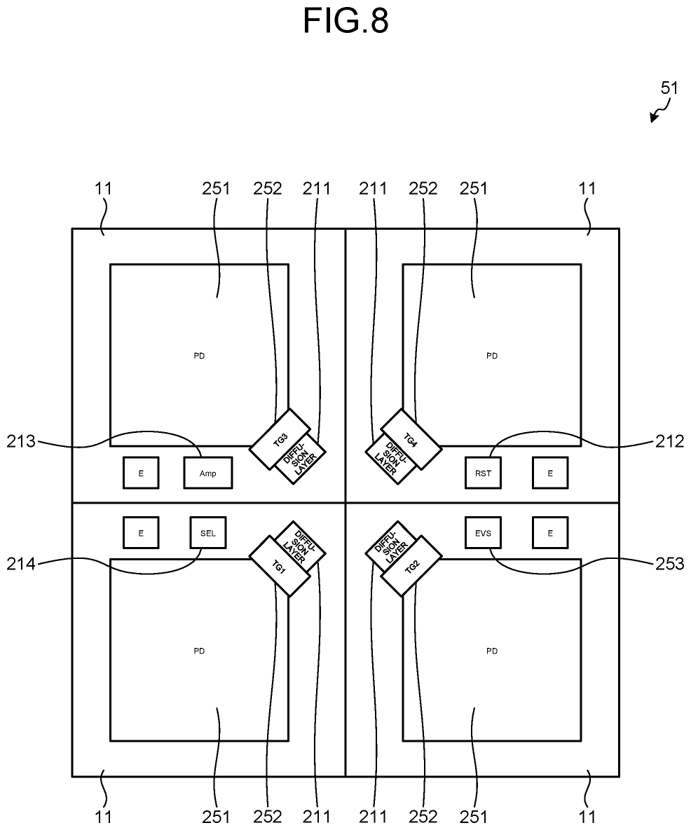

An example of a schematic configuration of the pixel 11 according to the present embodiment will be described with reference to FIG. 8. FIG. 8 is a diagram depicting an example of a schematic configuration of the pixel 11 according to the present embodiment.

As depicted in FIG. 8, four pixels 11 are provided. In the example of FIG. 8, the four pixels 11 function as the pixel block 51. The pixel block 51 is a sharing pixel unit. The photoelectric conversion element 251, the transfer transistor 252, and the floating diffusion layer 211 are provided for each pixel 11. Furthermore, the switching transistor 253, the reset transistor 212, the amplification transistor 213, and the selection transistor 214 are disposed, for example, in a surrounding region of each photoelectric conversion element 251 in one pixel block 51.

Here, one transfer transistor 252 is provided for each pixel 11. In this case, as compared with a case where two transfer transistors 252 are provided for each pixel 11, the area (volume) of the photoelectric conversion element 251 is increased, and the use efficiency of light is improved. Normally (conventionally), two transfer transistors (transfer gates) are mounted for one photoelectric conversion element 251 in order to perform both event detection and imaging.

### 1-7. Example of Operation of Imaging Element

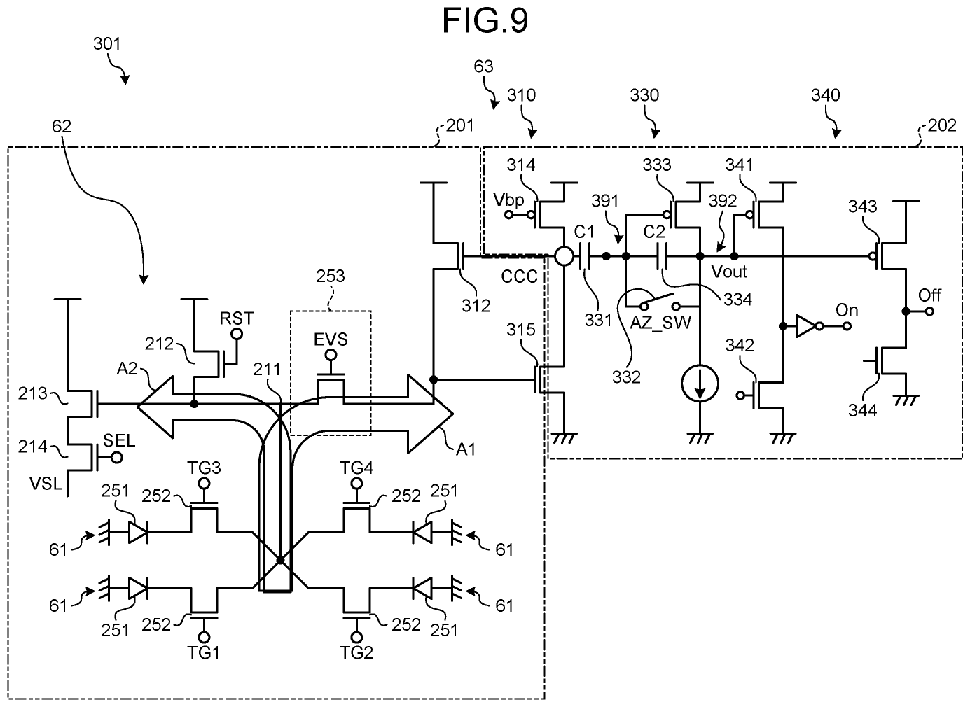

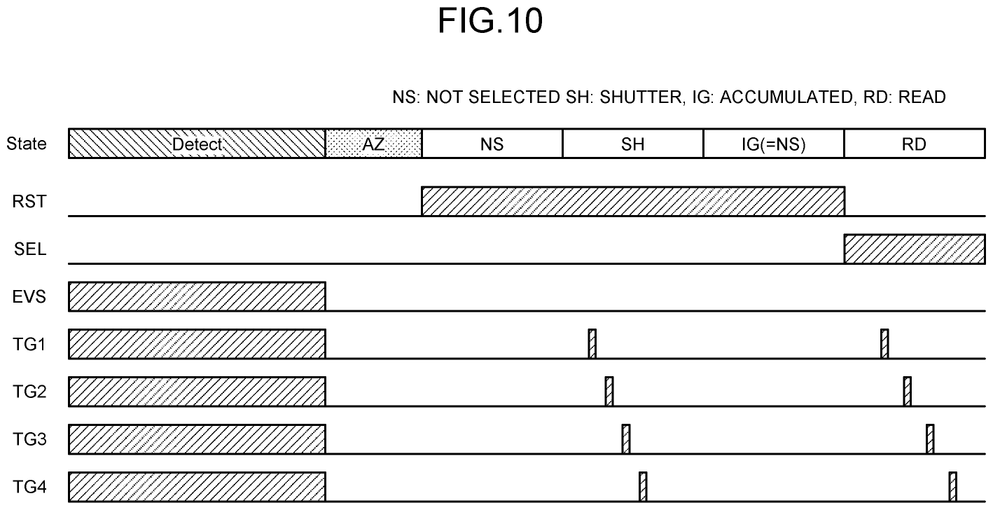

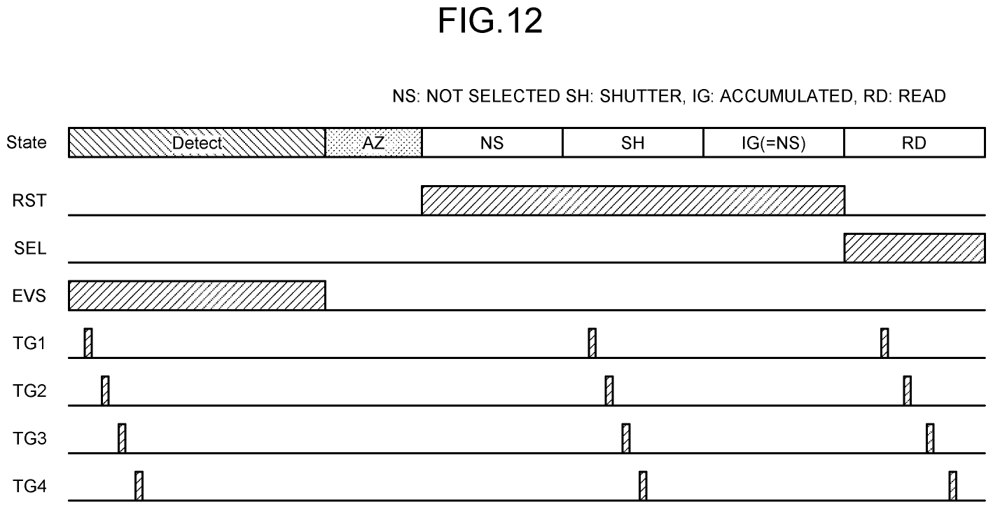

An example of an operation of the imaging element 200 according to the present embodiment will be described with reference to FIGS. 9 to 12. Each of FIGS. 9 to 12 is a diagram depicting an example of the operation of the imaging element 200 according to the present embodiment. Note that FIGS. 10 and 12 are timing charts each depicting an example of the operation of the imaging element 200 according to the present embodiment.

An operation phase (operation mode) of the imaging element 200 includes a detection phase (detection mode) and an imaging phase (imaging mode). As depicted in FIG. 9, the detection phase is a phase in which the switching transistor 253 is driven to be in an on state, making it possible to supply the electric signal from each light receiving section 61 to the event detecting section 63 (see an arrow A1). The imaging phase is a phase in which the switching transistor 253 is not driven and is in an off state, making it impossible to supply the electric signal from each light receiving section 61 to the event detecting section 63, and making it possible to supply the electric signal from each light receiving section 61 to the pixel signal generating section 62 (see arrow A2).

For example, the switching transistor 253 is switched to an on state or an off state by the control of the driving section 13, and switches the detection phase and the imaging phase. That is, the switching transistor 253 switches between a first electric path (see the arrow A1) through which the charge is supplied from each light receiving section 61 to the event detecting section 63 and a second electric path (see the arrow A2) through which the charge is supplied from each light receiving section 61 to the pixel signal generating section 62 depending on the operation phase.

As depicted in FIG. 10, in the detection phase (Detect), the driving section 13 raises the transfer signal EVS to be applied to the gate of the switching transistor 253 to a high level. Thus, the switching transistor 253 is turned on, and the electric signal can be supplied from each light receiving section 61 to the event detecting section 63.

Furthermore, the driving section 13 raises the transfer signal TG1, the transfer signal TG2, the transfer signal TG3, and the transfer signal TG4 to be applied to the gates of the respective transfer transistors 252 of the light receiving section 61 to a high level. Thus, each transfer transistor 252 of the light receiving section 61 is turned on, and the photoelectric current based on the charge generated in each photoelectric conversion element 251 of each light receiving section 61 is supplied to the event detecting section 63.

Note that, in the detection phase, the reset signal RST applied to the reset transistor 212 and the selection signal SEL applied to the selection transistor 214 are all maintained at the low level. Thus, during the detection phase, the reset transistor 212 and the selection transistor 214 are in an off state.

During this detection phase, when the event detecting section 63 of a certain pixel block 51 detects firing of an event, a request is transmitted to the arbiter section 14, but as described above, the output of the event detecting section 63 of the pixel block 51 is input to the arbiter section 14 as a request in units of pixel blocks. Thus, the arbiter section 14 returns a response to the request to the event detecting section 63 that has issued the request.

Upon receiving the response, the event detecting section 63 raises the detection signal (event detection signal) input to the driving section 13 and the signal processing section 16 to the high level for a predetermined period, for example. Note that, for example, it is assumed that the detection signal is a one-bit signal indicating a detection result of an on-event.

Note that, when the period of the detection phase elapses, the driving section 13 lowers the transfer signal EVS, the transfer signal TG1, the transfer signal TG2, the transfer signal TG3, and the transfer signal TG4 to a low level. Thus, the switching transistor 253 is turned off, and each transfer transistor 252 is turned off. Consequently, the supply of the photoelectric current from each light receiving section 61 to the event detecting section 63 is stopped, and the supply of the electric signal from each light receiving section 61 to the event detecting section 63 becomes impossible.

Thereafter, in the AZ phase (AZ), auto-zero is executed. For example, in the differential circuit 330, when the low-level auto zero signal XAZ is input, the differential signal Vout indicating the amount of change in light amount is set to an initial value according to the auto zero signal XAZ.

Next, in the imaging phase (NS, SH, IG (═NS), RD), the driving section 13 raises the reset signal RST to be applied to the gate of the reset transistor 212 to a high level. Thus, the reset transistor 212 is turned on. Thereafter, the driving section 13 raises the transfer signal TG1 to be applied to the gate of the switching transistor 253 to a high level over a certain pulse period in a period of SH (shutter). Thus, the switching transistor 253 corresponding to the transfer signal TG1 is turned on, and the photoelectric conversion element 251 connected to the switching transistor 253 is initialized (the charge is released). Similarly, the driving section 13 sequentially raises the transfer signal TG2, the transfer signal TG3, and the transfer signal TG4 to a high level and initializes the photoelectric conversion element 251.

The driving section 13 raises the selection signal SEL to be applied to the gate of the selection transistor 214 to a high level in a read (RD) period. Thus, the selection transistor 214 is turned on. Thereafter, in the RD period, the driving section 13 raises the transfer signal TG1 to be applied to the gate of the switching transistor 253 to a high level over a certain pulse period. Thus, the switching transistor 253 corresponding to the transfer signal TG1 is turned on, and the charge is transferred from the photoelectric conversion element 251 connected to the switching transistor 253 to the floating diffusion layer 211. Then, a voltage corresponding to the charge accumulated in the floating diffusion layer 211 appears in the vertical signal line VSL. In this manner, the voltage appearing in the vertical signal line VSL is read by the column processing section 15 as a pixel signal at the signal level of the light receiving section 61 and converted into a digital value. Similarly, the driving section 13 sequentially raises the transfer signal TG2, the transfer signal TG3, and the transfer signal TG4 to a high level, and executes reading of the charge from the photoelectric conversion element 251.

Thereafter, when the reading of the signal levels from all the light receiving sections 61 in the pixel block 51 to be read is completed, the driving section 13 changes from the imaging phase to the detection phase, and repeats the processing related to the detection phase and the imaging phase described above.

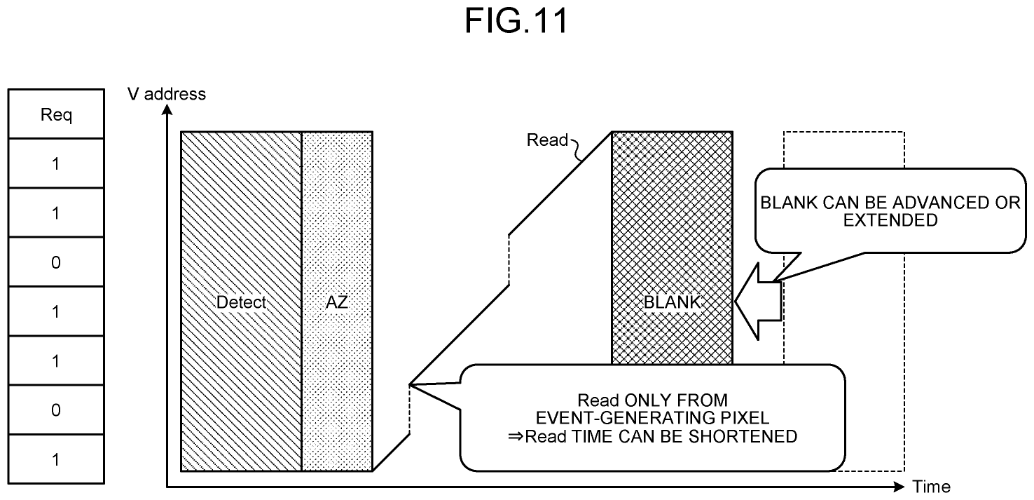

According to the processing related to the detection phase and the imaging phase, as depicted in FIG. 11, reading (Read) is performed only from the event-generating pixel. In the example of FIG. 11, the vertical axis is the address (V address), the horizontal axis is the time (Time), “1” indicates the presence of event detection, and “0” indicates “no event detection”. Since reading is performed only when “1”, the entire read time (read time) can be shortened. In addition, the blank time can be advanced or the blank time can be extended.

Note that it has been illustrated that, as depicted in FIG. 10, the transfer signal TG1, the transfer signal TG2, the transfer signal TG3, and the transfer signal TG4 of the respective transfer transistors 252 are simultaneously raised to a high level in the detection phase, and the photoelectric currents based on the charges generated in the individual photoelectric conversion elements 251 of the respective light receiving sections 61 are superimposed, but the present embodiment is not limited thereto. For example, as depicted in FIG. 12, the transfer signal TG1, the transfer signal TG2, the transfer signal TG3, and the transfer signal TG4 of the respective transfer transistors 252 may be sequentially raised to a high level, and the photoelectric currents based on the charges generated in the individual photoelectric conversion elements 251 of the respective light receiving sections 61 may be used without being superimposed.

As described above, in the present embodiment, the firing of the event (address event) is detected for each pixel block 51, and the pixel signals SIG are read from all the light receiving sections 61 belonging to the pixel block 51 in which the firing of the event is detected. For example, the imaging element 200 outputs the pixel signal SIG from each light receiving section 61 included in the pixel block 51 in which firing of an event is detected to the column processing section 15. Thus, it is possible to reduce the power consumption of the imaging element 200 and the processing amount of image processing as compared with a case where the pixel signal SIG is read from all the unit pixels regardless of the presence or absence of firing of an event.

### 1-8. Effects

As described above, according to the first embodiment, the switching element (for example, the switching transistor 253) switches between the first electric path through which the charge is supplied from the light receiving section 61 to the event detecting section 63 and the second electric path through which the charge is supplied from the light receiving section 61 to the pixel signal generating section 62. Consequently, the first electric path and the second electric path can be switched by a single switching element, and it is not necessary to mount two transfer gates for one photoelectric conversion element 251. Thus, since the area of the photoelectric conversion element 251 is increased and the use efficiency of light is improved, deterioration of pixel characteristics such as deterioration of image quality and erroneous detection of an event at low illuminance can be suppressed. In addition, even if miniaturization progresses, deterioration of pixel sensitivity can be suppressed, and deterioration of pixel characteristics can be suppressed.

Furthermore, the light receiving section 61 may constitute the pixel block 51 by a predetermined number, and the event detecting section 63 and the pixel signal generating section 62 may be provided for each pixel block 51. Thus, the configuration of the imaging element 200 can be simplified as compared with a case where the event detecting section 63 and the pixel signal generating section 62 are provided for each light receiving section 61 (pixel 11).

Furthermore, the light receiving section 61 may constitute a predetermined number of pixel blocks 51, and the event detecting section 63 may add the charges individually obtained from the predetermined number of the light receiving sections 61 in the pixel block 51, and generate the event detection signal on the basis of the added charges. Thus, the process can be simplified.

Furthermore, in a case where the event detection signal is generated by the event detecting section 63, the pixel signal generating section 62 may generate the pixel signal on the basis of the charge supplied from the light receiving section 61 used for generating the event detection signal. Thus, regardless of the presence or absence of the generation of the event signal, the power consumption of the imaging element 200 and the processing amount of the image processing can be reduced as compared with the case where the pixel signal is generated from all the light receiving sections 61 (pixels 11).

### 2. Second Embodiment

### 2-1. Example of Schematic Configuration of Pixel Circuit

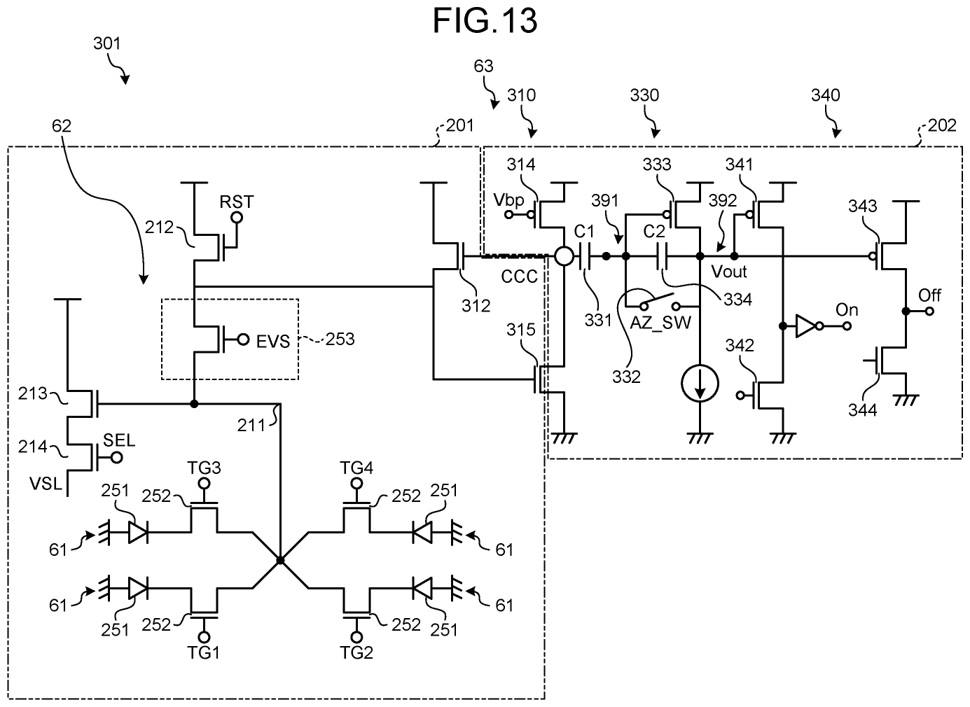

An example of a schematic configuration of the pixel circuit 301 according to the present embodiment will be described with reference to FIG. 13. FIG. 13 is a diagram depicting an example of a schematic configuration of the pixel circuit 301 according to the present embodiment. Hereinafter, differences from the first embodiment will be mainly described, and other descriptions will be omitted.

As depicted in FIG. 13, the switching transistor 253 is connected in series to the reset transistor 212. Note that, in the first embodiment, the switching transistor 253 is connected in parallel to the reset transistor 212. In this parallel structure, the photoelectric conversion element 251 always has an extra capacitance, and conversion efficiency decreases. Although there is no problem during normal driving, a series structure as depicted in FIG. 13 is suitable in a use case in which the conversion efficiency is desired to be increased.

### 2-2. Effects

As described above, according to the second embodiment, effects similar to those of the first embodiment can be obtained. That is, deterioration of the pixel characteristics can be suppressed. Further, the switching element (for example, the switching transistor 253) is connected in series to the reset element (for example, the reset transistor 212). Consequently, the conversion efficiency can be improved, and thus the pixel characteristics can be improved.

### 3. Third Embodiment

### 3-1. Example of Schematic Configuration of Pixel Circuit

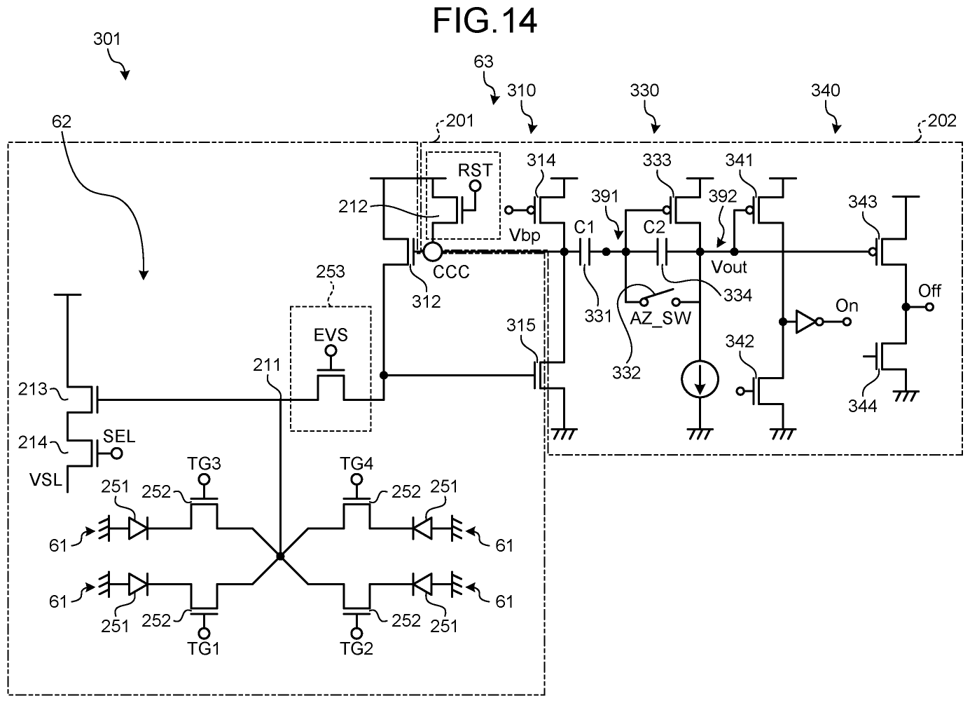

An example of a schematic configuration of the pixel circuit 301 according to the present embodiment will be described with reference to FIG. 14. FIG. 14 is a diagram depicting an example of a schematic configuration of the pixel circuit 301 according to the present embodiment. Hereinafter, differences from the first embodiment will be mainly described, and other descriptions will be omitted.

As depicted in FIG. 14, the reset transistor 212 is provided in the detection chip 202. Thus, since the number of transistors mounted on the light receiving chip 201 is reduced, the area (volume) of the photoelectric conversion element 251 is enlarged, so that the use efficiency of light (for example, light receiving efficiency) can be enhanced. Note that the source of the reset transistor 212 is connected to the gate of the N-type transistor 312, and the drain thereof is connected to the power supply terminal. By connecting the drain of the reset transistor 212 to the power supply terminal, the photoelectric conversion element 251 can be reset without a driving problem.

### 3-2. Effects

As described above, according to the third embodiment, effects similar to those of the first embodiment can be obtained. That is, deterioration of the pixel characteristics can be suppressed. Further, the reset element (for example, the reset transistor 212) is provided on the second substrate (for example, the detection chip 202). Thus, the number of elements of the first substrate (for example, the light receiving chip 201) is reduced, and the use efficiency of light can be improved, so that the pixel characteristics can be improved.

### 4. Fourth Embodiment

### 4-1. Example of Schematic Configuration of Pixel Circuit

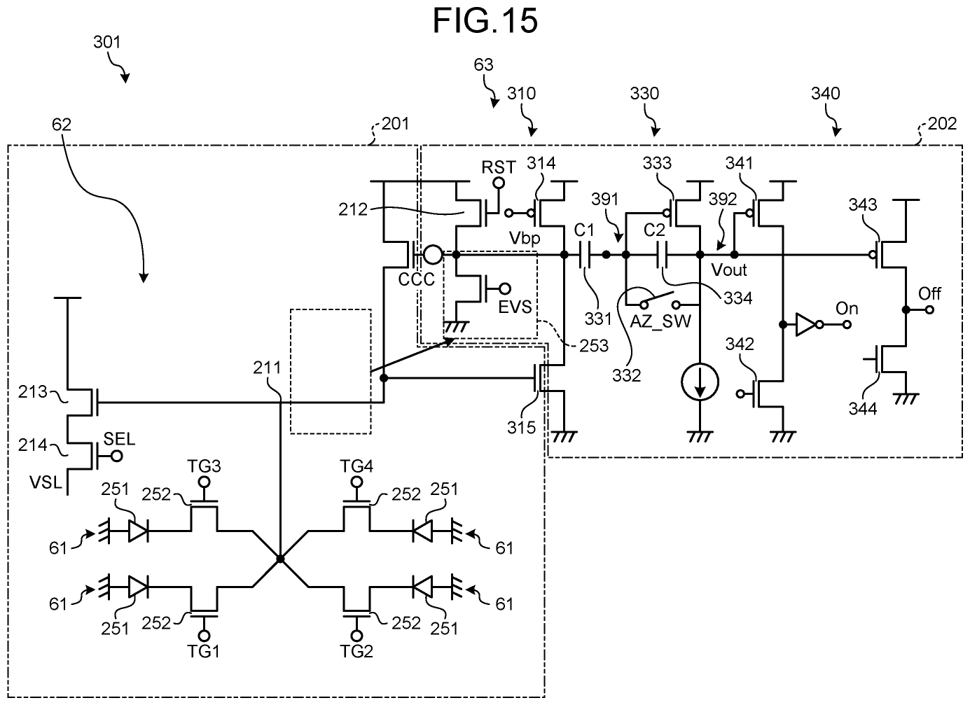

An example of a schematic configuration of the pixel circuit 301 according to the present embodiment will be described with reference to FIG. 15. FIG. 15 is a diagram depicting an example of a schematic configuration of the pixel circuit 301 according to the present embodiment. Hereinafter, differences from the third embodiment will be mainly described, and other descriptions will be omitted.

As depicted in FIG. 15, the switching transistor 253 is provided in the detection chip 202. Thus, since the number of transistors mounted on the light receiving chip 201 is reduced, the area (volume) of the photoelectric conversion element 251 is enlarged, so that the use efficiency of light (for example, light receiving efficiency) can be enhanced. Note that the source of the switching transistor 253 is connected to the gate of the N-type transistor 312, and the drain thereof is connected to the ground terminal.

Here, even if the switching transistor 253 is not directly connected to the photoelectric conversion element 251 (for example, even if it is not immediately below the photoelectric conversion element 251), in the event detecting section 63, the difference signal can be read out by pulling out the photoelectric current (photocurrent) flowing through the photoelectric conversion element 251 by a constant current by the reset transistor 212. Thus, if the reset transistor 212 can be turned off, the pixel signal generating section 62 can read the switching transistor 253 even if it is not immediately below the photoelectric conversion element 251. In a case where event detection (reading for event detection) is performed, the selection transistor 214 of the pixel signal generating section 62 is turned off, and in a case where reading for imaging is performed, the switching transistor 253 is turned off, and the reset transistor 212 is turned off, so that reading is performed by the event detecting section 63 without drawing a current.

### 4-2. Effects

As described above, according to the fourth embodiment, effects similar to those of the third embodiment can be obtained. That is, deterioration of the pixel characteristics can be suppressed, and the pixel characteristics can be improved. Furthermore, the switching element (for example, the switching transistor 253) is provided on the second substrate (for example, the detection chip 202) in addition to the reset element (for example, the reset transistor 212). Thus, the number of elements of the first substrate (for example, the light receiving chip 201) is reduced, and use efficiency of light can be improved, so that the pixel characteristics can be further improved.

### 5. Fifth Embodiment

### 5-1. Example of Schematic Configuration of Pixel Circuit

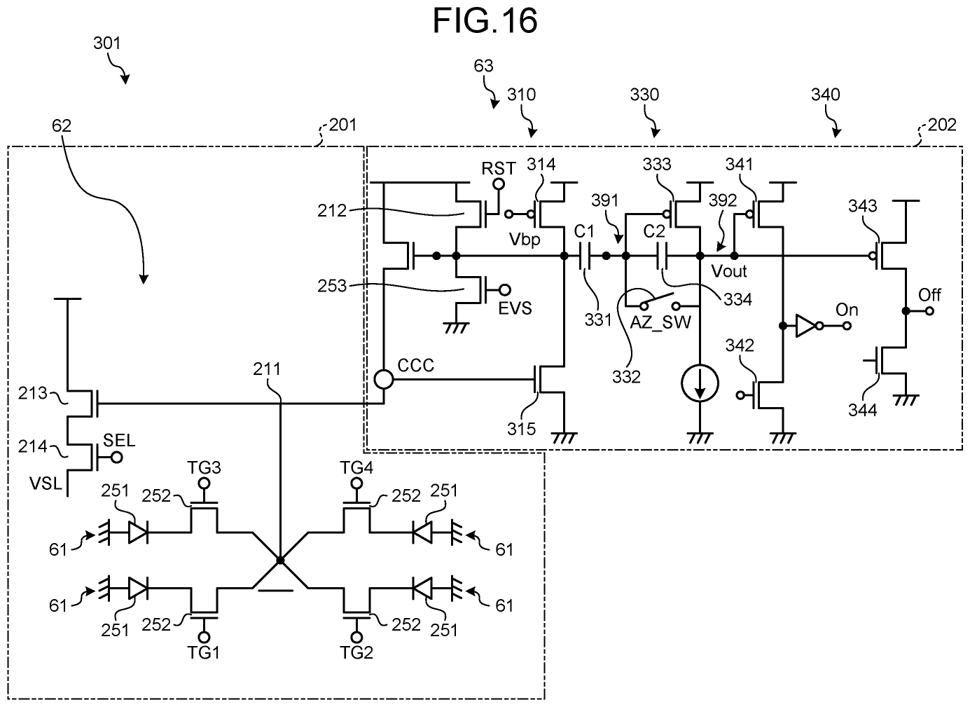

An example of a schematic configuration of the pixel circuit 301 according to the present embodiment will be described with reference to FIG. 16. FIG. 16 is a diagram depicting an example of a schematic configuration of the pixel circuit 301 according to the present embodiment. Hereinafter, differences from the fourth embodiment will be mainly described, and other descriptions will be omitted.

As depicted in FIG. 16, the N-type transistor 312 and the N-type transistor 315 are provided in the detection chip 202. Therefore, the event detecting section 63 is provided in the detection chip 202. In addition, the light receiving chip 201 and the detection chip 202 are bonded by Cu-Cu bonding (CCC). The position of the Cu-Cu bonding is not the node of the P-type transistor 314 according to the fourth embodiment, but the terminal of the photoelectric conversion element 251, specifically, the terminal of the transfer transistor 252 connected to the photoelectric conversion element 251.

Here, as described above, the N-type transistor 312 and the N-type transistor 315 are provided in the detection chip 202. Thus, all the transistors involved in the event detecting section 63 can be placed on the detection chip 202. Therefore, since the number of transistors mounted on the light receiving chip 201 is reduced, the area (volume) of the photoelectric conversion element 251 is enlarged, so that the use efficiency of light (for example, light receiving efficiency) can be enhanced.

### 5-2. Effects

As described above, according to the fifth embodiment, effects similar to those of the fourth embodiment can be obtained. That is, deterioration of the pixel characteristics can be suppressed, and the pixel characteristics can be improved. Furthermore, the event detecting section 63 is provided on the second substrate (for example, the detection chip 202). Thus, the number of elements of the first substrate (for example, the light receiving chip 201) is reduced, and the use efficiency of light can be improved, so that the pixel characteristics can be improved.

### 6. Sixth Embodiment

### 6-1. Example of Schematic Configuration of Pixel

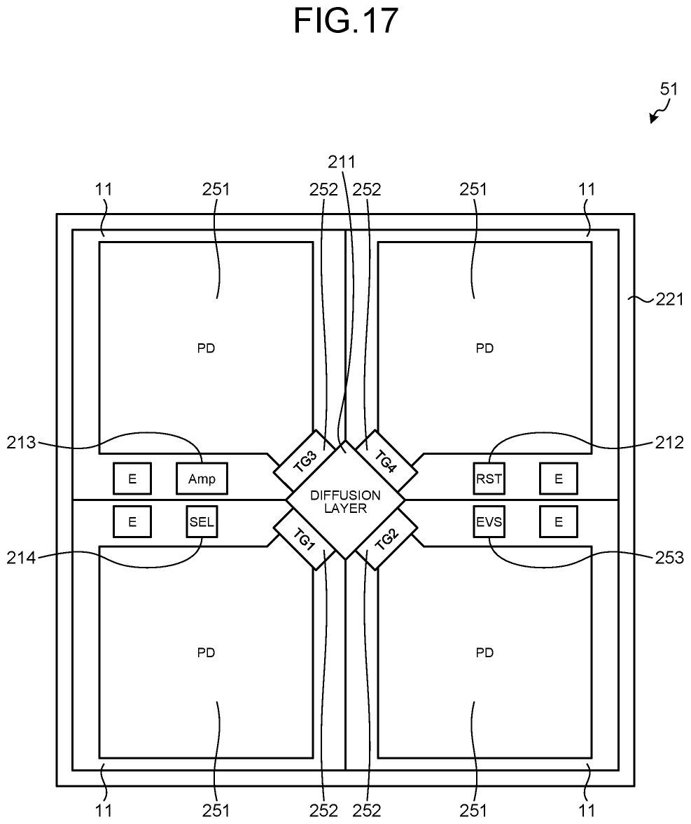

An example of a schematic configuration of the pixel 11 according to the present embodiment will be described with reference to FIG. 17. FIG. 17 is a diagram depicting an example of a schematic configuration of the pixel 11 according to the present embodiment. Hereinafter, differences from the first embodiment (see FIG. 8) will be mainly described, and other descriptions will be omitted.

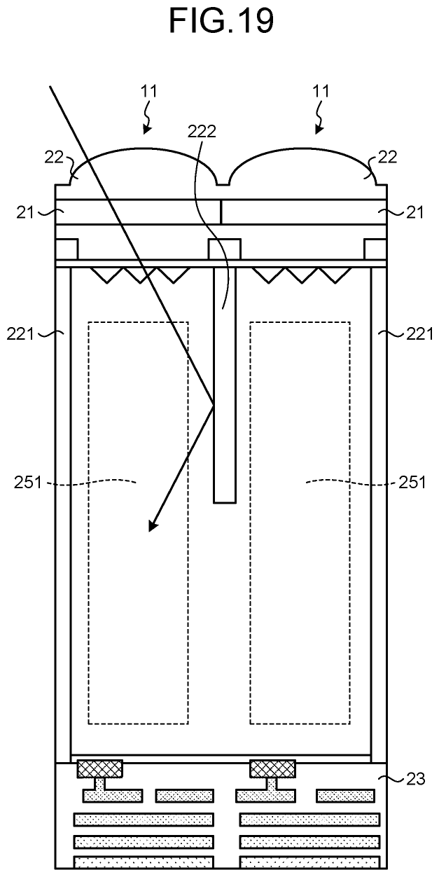

As depicted in FIG. 17, the pixel block 51 including a predetermined number (for example, four) of pixels 11 is partitioned by a pixel block separator 221. For example, the pixel block separator 221 is formed so that a shape viewed from a light incident surface (light receiving surface) on which light is incident is a lattice shape. The pixel block separator 221 functions as a penetrating barrier that separates the pixel block 51 and reflects light. Further, the floating diffusion layer 211 is common to the four pixels 11. Note that the pixel block separator 221 is, for example, a barrier having a length equal to or more than a length in a height direction of the photoelectric conversion element 251 (see FIG. 19).

Here, in the imaging element 200, since near infrared (NIR) light is often used, a physical penetrating barrier is usually formed between the pixels 11. However, by forming a penetrating barrier for each pixel 11, the area of the photoelectric conversion element 251 is reduced, and a structure with low use efficiency of light is obtained. Accordingly, in the present embodiment, the use area of the photoelectric conversion element 251 is further secured in consideration of the formation structure of the pixel barrier. In the pixel block 51 (sharing pixel), on the premise that the event signals of the respective light receiving sections 61 are added and read out, NIR color mixture in the sharing pixel is not noticeable, and thus the formation cycle of the penetrating barrier is also one in the pixel block 51. Thus, it is possible to prevent a process difficulty level due to miniaturization from increasing and to secure a space for placing a transistor between the pixels 11 in the shared pixel. Furthermore, the floating diffusion layer 211 can be shared, and the area of the photoelectric conversion element 251 can be secured.

### 6-2. Effect

As described above, according to the sixth embodiment, effects similar to those of the first embodiment can be obtained. That is, deterioration of the pixel characteristics can be suppressed. Furthermore, the pixel block 51 including respective pixels 11 (respective light receiving sections 61) is partitioned by the pixel block separator 221, and the floating diffusion layer 211 is common to a predetermined number (for example, four) of pixels 11. Thus, light color mixture (for example, NIR visible light color mixture) between the pixel blocks 51 can be suppressed, and the use efficiency of light can be improved, so that the pixel characteristics can be improved.

Furthermore, the pixel block separator 221 may be a barrier having a length equal to or more than the length of the photoelectric conversion element 251 in the height direction. Thus, light color mixture (for example, NIR visible light color mixture) between the pixel blocks 51 can be reliably suppressed, so that the pixel characteristics can be further improved.

### 7. Seventh Embodiment

### 7-1. Example of Schematic Configuration of Pixel

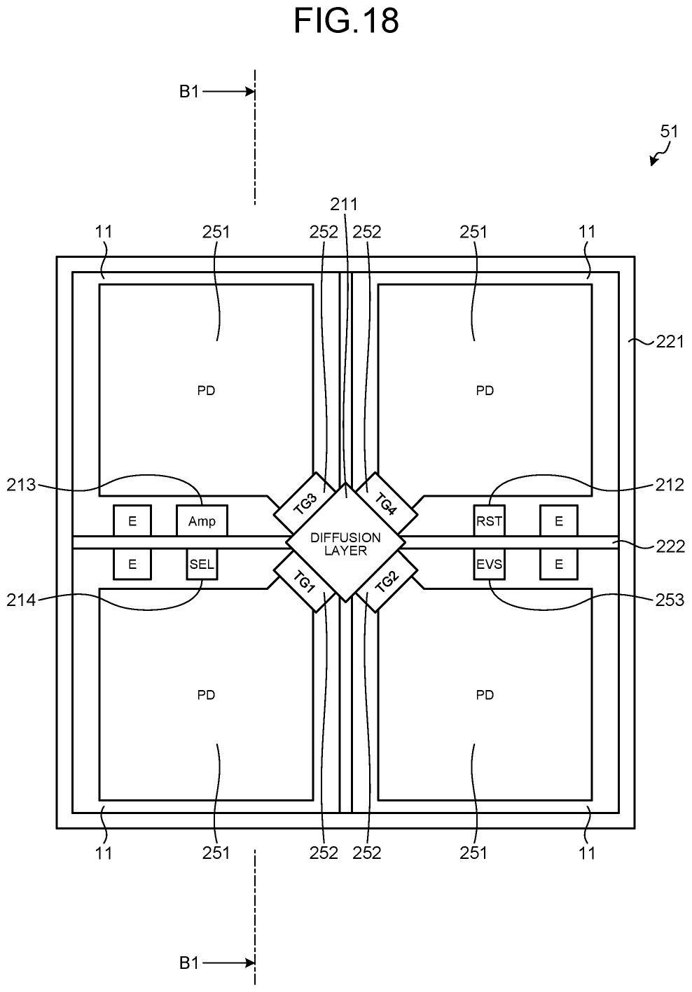

An example of a schematic configuration of the pixel 11 according to the present embodiment will be described with reference to FIGS. 18 and 19. FIGS. 18 and 19 are views each depicting an example of a schematic configuration of the pixel 11 according to the present embodiment. Note that FIG. 19 is a cross-sectional view taken along line B1-B1 in FIG. 18. Hereinafter, differences from the sixth embodiment (see FIG. 17) will be mainly described, and other descriptions will be omitted.

As depicted in FIGS. 18 and 19, a predetermined number (for example, four) of pixels 11 in the pixel block 51 are partitioned by a non-penetrating pixel separator 222. For example, the pixel separator 222 is formed so that a shape viewed from the light incident surface (light receiving surface) on which light is incident is a lattice shape. The pixel separator 222 functions as a non-penetrating barrier that separates each pixel 11 and reflects light.

As depicted in FIG. 19, the pixel separator 222 is, for example, a barrier having a length shorter than the length in the height direction of the photoelectric conversion element 251. The length of the pixel separator 222 (the length in the vertical direction in FIG. 19) is, for example, about half the length of the pixel block separator 221 (as an example, 6 μm).

Note that, in the example of FIG. 19, the color filter 21, a light receiving lens 22, and a wiring layer 23 are depicted. One color filter 21, one light receiving lens 22, and one photoelectric conversion element 251 are provided for each pixel 11. The wiring layer 23 is common to all the pixels 11.

Here, depending on the color filter array and the sharing pixel unit, for example, in a 2×2 pixel Bayer array, NIR light color mixing at the time of detecting an event can be suppressed by the pixel block separator 221, but visible light color mixing may become a problem. Thus, in order to suppress color mixing of the imaging pixels, the pixel separator 222 serving as a non-penetrating barrier is formed. Usually, the imaging element 200 is a sensor for NIR light, and in consideration of the penetration length of visible light, it is assumed that a through barrier is not necessary. Furthermore, the pixel separator 222 serving as a non-penetrating barrier allows the floating diffusion layer 211 to be shared among the pixels 11, and the area of the photoelectric conversion element 251 can be secured.

### 7-2. Effects

As described above, according to the seventh embodiment, effects similar to those of the sixth embodiment can be obtained. That is, deterioration of the pixel characteristics can be suppressed, and the pixel characteristics can be improved. Furthermore, each pixel 11 (each light receiving section 61) in the pixel block 51 is partitioned by the pixel separator 222. Thus, light color mixture (for example, visible light color mixture) between the pixels 11 in the pixel block 51 can be suppressed, so that the pixel characteristics can be further improved.

Furthermore, the pixel separator 222 may be a barrier having a length shorter than the length in the height direction of the photoelectric conversion element 251. Thus, light color mixture (for example, visible light color mixture) between the pixel blocks 51 can be reliably suppressed, so that the pixel characteristics can be further improved.

### 8. Eighth Embodiment

### 8-1. Example of Schematic Configuration of Pixel

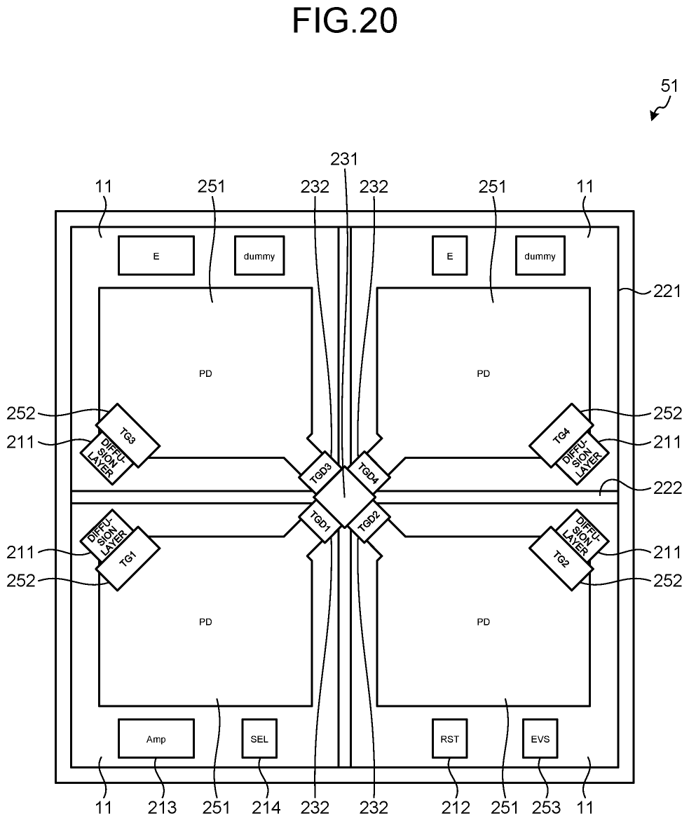

An example of a schematic configuration of the pixel 11 according to the present embodiment will be described with reference to FIG. 20. FIG. 20 is a diagram depicting an example of a schematic configuration of the pixel 11 according to the present embodiment. Hereinafter, differences from the seventh embodiment (see FIG. 18) will be mainly described, and other descriptions will be omitted.

As depicted in FIG. 20, an overflow drain layer 231 is formed at the center of the pixel block 51 (in plan view in FIG. 20). A transfer transistor 232 is provided around the overflow drain layer 231 for each pixel 11. The transfer transistor 232 functions as an overflow gate. Note that the floating diffusion layer 211 and the transfer transistor 252 are also provided for each pixel 11, and are disposed at positions different from the positions where the overflow drain layer 231 and the transfer transistor 232 are provided.

Here, with the overflow drain function mounted on the pixel block 51, the area (volume) of the photoelectric conversion element 251 can be efficiently used. By sharing the overflow drain layer 231 in each pixel 11 in the pixel block 51, the area of the photoelectric conversion element 251 can be secured. Note that the overflow drain function is a function of suppressing blooming, for example, by allowing an excessive charge generated by strong incident light to flow into the overflow drain layer 231.

### 8-2. Effect

As described above, according to the eighth embodiment, effects similar to those of the seventh embodiment can be obtained. That is, deterioration of the pixel characteristics can be suppressed, and the pixel characteristics can be improved. Further, each pixel 11 (each light receiving section 61) in the pixel block 51 shares the overflow drain layer 231. Thus, the use efficiency of light can be enhanced, so that the pixel characteristics can be further improved.

### 9. Other Embodiments

The processing according to the above-described embodiment (or modification) may be performed in various different modes (modifications) other than the above-described embodiment. For example, among the processes described in the above embodiments, all or part of the processes described as being performed automatically can be performed manually, or all or part of the processes described as being performed manually can be performed automatically by a publicly known method. Further, the processing procedure, specific name, and information including various data and parameters depicted in the document and the drawings can be arbitrarily changed unless otherwise specified. For example, the various types of information depicted in each figure are not limited to the depicted information.

Further, each component of each device depicted in the drawings is functionally conceptual, and is not necessarily physically configured as depicted in the drawings. That is, a specific form of distribution and integration of each device is not limited to the depicted form, and all or a part thereof can be functionally or physically distributed and integrated in any unit according to various loads, usage conditions, and the like.

In addition, the above-described embodiments (or modifications) can be appropriately combined within a range that does not contradict processing contents. Further, the effects described in the present description are merely examples and are not limited, and other effects may be provided.

### 10. Application Example

A technology according to the present disclosure is applicable to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a boat, a robot, a construction machine, an agricultural machine (tractor), and the like.

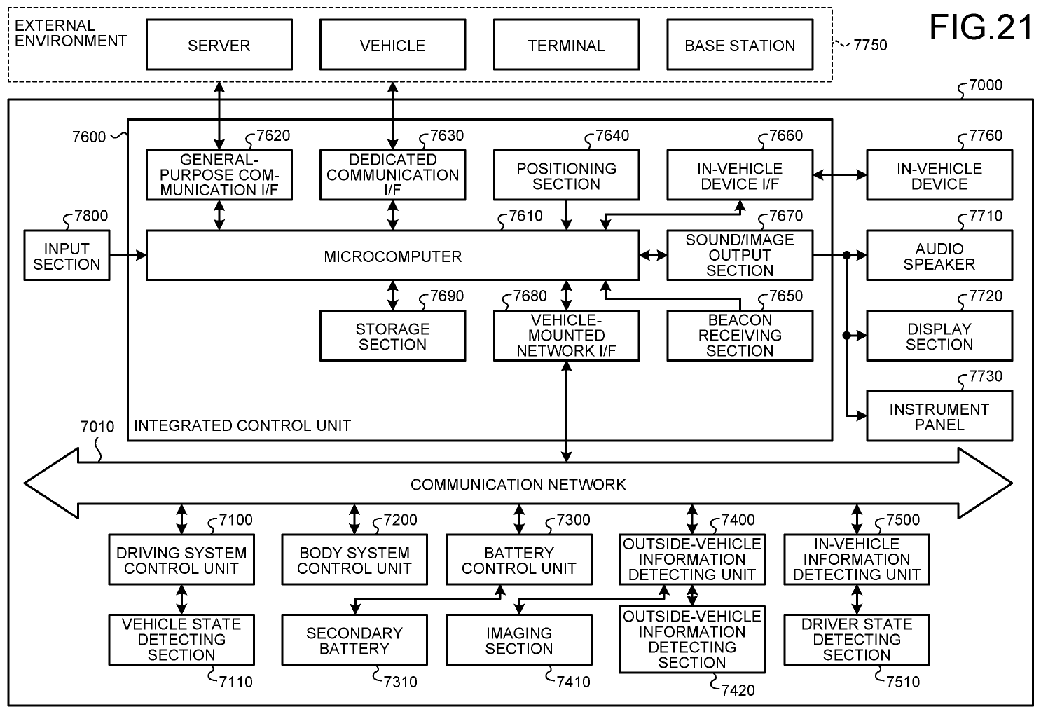

FIG. 21 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 21, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 21 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

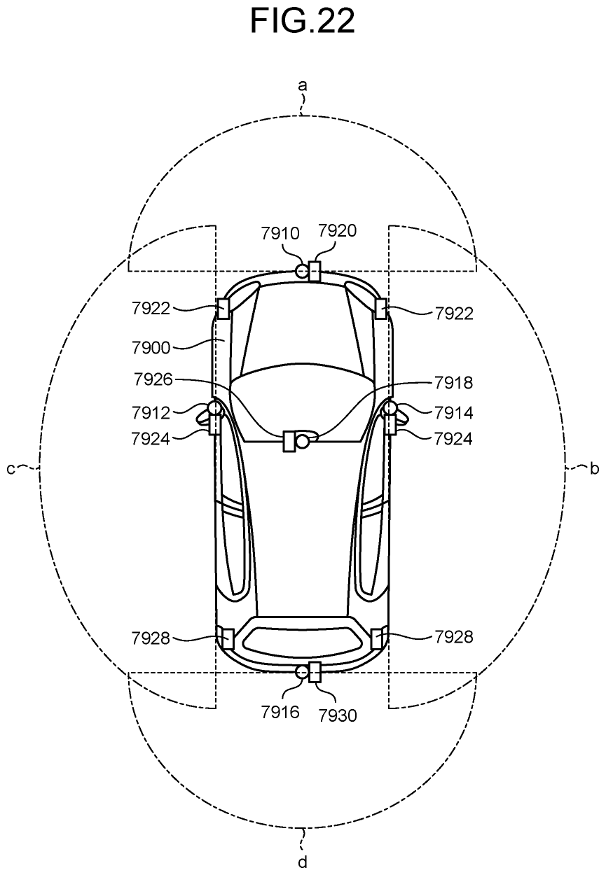

FIG. 22 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 21, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA) , or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a

communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 21, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal. Incidentally, at least two control units connected to each other via the communication network 7010 in the example depicted in FIG. 21 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the imaging device 100 described in each embodiment (including modifications) can be mounted on any control unit or the like. Furthermore, it is also possible to provide a computer-readable recording medium storing such a computer program. The recording medium is, for example, a magnetic disk, an optical disk, a magneto-optical disk, a flash memory, or the like. In addition, the computer program described above may be distributed via, for example, a network without using the recording medium.

In the vehicle control system 7000 described above, the imaging device 100 described in each embodiment (including modifications) can be applied to the integrated control unit 7600 of the application example depicted in FIG. 21. For example, the control section 130, the recording section (storage section) 120, and the like of the imaging device 100 may be implemented by the microcomputer 7610 or the storage section 7690 of the integrated control unit 7600. Furthermore, the imaging device 100 described in each embodiment can be applied to the imaging section 7410 and the outside-vehicle information detecting section 7420 according to the application example depicted in FIG. 21, for example, the imaging sections 7910, 7912, 7914, 7916, and 7918 and the outside-vehicle information detecting sections 7920 to 7930, and the like according to the application example depicted in FIG. 22. By using the imaging device 100 described in each embodiment, deterioration of the pixel characteristics can also be suppressed in the vehicle control system 7000.

Furthermore, at least some components of the imaging device 100 described in each embodiment (including modifications) may be implemented in a module (for example, an integrated circuit module including one die) for the integrated control unit 7600 of the application example depicted in FIG. 21. Alternatively, a part of the imaging device 100 described in each embodiment may be implemented by a plurality of control units of the vehicle control system 7000 depicted in FIG. 21.

### 11. Appendix

Note that the present technology can also have the following configurations.

(1)

An imaging element, comprising:

a light receiving section that includes a photoelectric conversion element that generates a charge;

an event detecting section that generates an event detection signal on a basis of the charge supplied from the light receiving section;

a pixel signal generating section that generates a pixel signal on a basis of the charge supplied from the light receiving section; and

a switching element that switches between a first electric path through which the charge is supplied from the light receiving section to the event detecting section and a second electric path through which the charge is supplied from the light receiving section to the pixel signal generating section.

(2)

The imaging element according to (1), further comprising:

a floating diffusion layer that accumulates the charge supplied from the photoelectric conversion element, wherein

the pixel signal generating section includes a reset element for initializing the charge accumulated in the floating diffusion layer, and

the switching element is connected in series to the reset element.

(3)

The imaging element according to (1), further comprising:

a floating diffusion layer that accumulates the charge supplied from the photoelectric conversion element, wherein

the pixel signal generating section includes a reset element for initializing the charge accumulated in the floating diffusion layer,

the light receiving section and the switching element are provided on a first substrate, and

the reset element is provided on a second substrate stacked on the first substrate.

(4)

The imaging element according to any one of (1) to (3), wherein

the light receiving section and the switching element are provided on different substrates.

(5)

The imaging element according to (4), wherein

the light receiving section is provided on a first substrate, and

the switching element is provided on a second substrate stacked on the first substrate.

(6)

The imaging element according to (5), further comprising:

a floating diffusion layer that accumulates the charge supplied from the photoelectric conversion element, wherein

the pixel signal generating section includes a reset element for initializing the charge accumulated in the floating diffusion layer, and

the reset element is provided on the second substrate.

(7)

The imaging element according to (5), wherein

the event detecting section is provided on the second substrate.

(8)

The imaging element according to any one of (1) to (7), wherein

a predetermined number of the light receiving sections constitute a pixel block, and

the imaging element further comprises a pixel block separator that separates the pixel block and reflects light.

(9)

The imaging element according to (8), wherein

the pixel block separator is a barrier having a length equal to or more than a length in a height direction of the photoelectric conversion element.

(10)

The imaging element according to any one of (1) to (7), wherein

a predetermined number of the light receiving sections constitute a pixel block, and

the imaging element further comprises a pixel separator that separates a predetermined number of the light receiving sections in the pixel block and reflects light.

(11)

The imaging element according to (10), wherein

the pixel separator is a barrier having a length shorter than a length in a height direction of the photoelectric conversion element.

(12)

The imaging element according to (10), further comprising:

a floating diffusion layer that accumulates the charge supplied from the photoelectric conversion element of each of the predetermined number of the light receiving sections in the pixel block.

(13)

The imaging element according to any one of (1) to (7), wherein

a predetermined number of the light receiving sections constitute a pixel block,

the imaging element further comprises

a pixel block separator that separates the pixel block and reflects light, and

a pixel separator that separates a predetermined number of the light receiving sections in the pixel block and reflects light.

(14)

The imaging element according to (13), wherein

the pixel block separator is a barrier having a length equal to or more than a length in a height direction of the photoelectric conversion element, and

the pixel separator is a barrier having a length shorter than a length in a height direction of the photoelectric conversion element.

(15)

The imaging element according to any one of (1) to (14), wherein

a predetermined number of the light receiving sections constitute a pixel block, and

the imaging element further comprises an overflow drain layer for a predetermined number of the light receiving sections in the pixel block.

(16)

The imaging element according to any one of (1) to (15), wherein

a predetermined number of the light receiving sections constitute a pixel block, and

the event detecting section and the pixel signal generating section are provided for each of the pixel blocks.

(17)

The imaging element according to any one of (1) to (16), wherein

a predetermined number of the light receiving sections constitute a pixel block, and

the event detecting section adds the charges individually obtained from a predetermined number of the light receiving sections in the pixel block, and generates the event detection signal on a basis of the added charges.

(18)

The imaging element according to any one of (1) to (17), wherein

in a case where the event detection signal is generated by the event detecting section, the pixel signal generating section generates the pixel signal on a basis of the charge supplied from the light receiving section.

(19)

An imaging device, comprising:

an imaging lens; and

an imaging element, wherein

the imaging element includes

a light receiving section that includes a photoelectric conversion element that generates a charge,

an event detecting section that generates an event detection signal on a basis of the charge supplied from the light receiving section,

a pixel signal generating section that generates a pixel signal on a basis of the charge supplied from the light receiving section, and

a switching element that switches between a first electric path through which the charge is supplied from the light receiving section to the event detecting section and a second electric path through which the charge is supplied from the light receiving section to the pixel signal generating section.

(20)

A method for controlling an imaging element, the method comprising:

by a switching element, switching between a first electric path through which a charge is supplied from a light receiving section including a photoelectric conversion element that generates the charge to an event detecting section that generates an event detection signal on a basis of the charge, and a second electric path through which the charge is supplied from the light receiving section to a pixel signal generating section that generates a pixel signal on a basis of the charge.

(21)

An imaging device including the imaging element according to any one of (1) to (18).

(22)

A method for controlling an imaging element, the method including controlling the imaging element according to any one of (1) to (18).

### Reference Signs List

11 PIXEL
12 PIXEL ARRAY SECTION
13 DRIVING SECTION
14 ARBITER SECTION
15 COLUMN PROCESSING SECTION
16 SIGNAL PROCESSING SECTION
21 COLOR FILTER
22 LIGHT RECEIVING LENS
23 WIRING LAYER
51 PIXEL BLOCK
61 LIGHT RECEIVING SECTION
62 PIXEL SIGNAL GENERATING SECTION
63 EVENT DETECTING SECTION
100 IMAGING DEVICE
110 IMAGING LENS
120 RECORDING SECTION
130 CONTROL SECTION
139 SIGNAL LINE
200 IMAGING ELEMENT
201 LIGHT RECEIVING CHIP
202 DETECTION CHIP
209 SIGNAL LINE
211 FLOATING DIFFUSION LAYER
212 RESET TRANSISTOR
213 AMPLIFICATION TRANSISTOR
214 SELECTION TRANSISTOR
220 SIGNAL PROCESSING SECTION
221 PIXEL BLOCK SEPARATOR
222 PIXEL SEPARATOR
231 OVERFLOW DRAIN LAYER
232 TRANSFER TRANSISTOR
251 PHOTOELECTRIC CONVERSION ELEMENT
252 TRANSFER TRANSISTOR
253 SWITCHING TRANSISTOR
301 PIXEL CIRCUIT
310 CURRENT-VOLTAGE CONVERSION SECTION
312 N-TYPE TRANSISTOR
314 P-TYPE TRANSISTOR
315 N-TYPE TRANSISTOR
330 DIFFERENTIAL CIRCUIT
331 CAPACITOR
332 SWITCH
333 P-TYPE TRANSISTOR
334 CAPACITOR
340 COMPARATOR
341 P-TYPE TRANSISTOR
342 N-TYPE TRANSISTOR
343 P-TYPE TRANSISTOR
344 N-TYPE TRANSISTOR
350 TRANSFER SECTION
391 INPUT TERMINAL
392 OUTPUT TERMINAL

1. An imaging element, comprising:
a light receiving section that includes a photoelectric conversion element that generates a charge;
an event detecting section that generates an event detection signal on a basis of the charge supplied from the light receiving section;
a pixel signal generating section that generates a pixel signal on a basis of the charge supplied from the light receiving section; and
a switching element that switches between a first electric path through which the charge is supplied from the light receiving section to the event detecting section and a second electric path through which the charge is supplied from the light receiving section to the pixel signal generating section.

2. The imaging element according to claim 1, further comprising:
a floating diffusion layer that accumulates the charge supplied from the photoelectric conversion element, wherein
the pixel signal generating section includes a reset element for initializing the charge accumulated in the floating diffusion layer, and
the switching element is connected in series to the reset element.

3. The imaging element according to claim 1, further comprising:
a floating diffusion layer that accumulates the charge supplied from the photoelectric conversion element, wherein
the pixel signal generating section includes a reset element for initializing the charge accumulated in the floating diffusion layer,
the light receiving section and the switching element are provided on a first substrate, and
the reset element is provided on a second substrate stacked on the first substrate.

4. The imaging element according to claim 1, wherein
the light receiving section and the switching element are provided on different substrates.

5. The imaging element according to claim 4, wherein
the light receiving section is provided on a first substrate, and
the switching element is provided on a second substrate stacked on the first substrate.

6. The imaging element according to claim 5, further comprising:
a floating diffusion layer that accumulates the charge supplied from the photoelectric conversion element, wherein
the pixel signal generating section includes a reset element for initializing the charge accumulated in the floating diffusion layer, and
the reset element is provided on the second substrate.

7. The imaging element according to claim 5, wherein
the event detecting section is provided on the second substrate.

8. The imaging element according to claim 1, wherein
a predetermined number of the light receiving sections constitute a pixel block, and
the imaging element further comprises a pixel block separator that separates the pixel block and reflects light.

9. The imaging element according to claim 8, wherein
the pixel block separator is a barrier having a length equal to or more than a length in a height direction of the photoelectric conversion element.

10. The imaging element according to claim 1, wherein
a predetermined number of the light receiving sections constitute a pixel block, and
the imaging element further comprises a pixel separator that separates a predetermined number of the light receiving sections in the pixel block and reflects light.

11. The imaging element according to claim 10, wherein
the pixel separator is a barrier having a length shorter than a length in a height direction of the photoelectric conversion element.

12. The imaging element according to claim 10, further comprising:
a floating diffusion layer that accumulates the charge supplied from the photoelectric conversion element of each of the predetermined number of the light receiving sections in the pixel block.

13. The imaging element according to claim 1, wherein
a predetermined number of the light receiving sections constitute a pixel block,
the imaging element further comprises
a pixel block separator that separates the pixel block and reflects light, and
a pixel separator that separates a predetermined number of the light receiving sections in the pixel block and reflects light.

14. The imaging element according to claim 13, wherein
the pixel block separator is a barrier having a length equal to or more than a length in a height direction of the photoelectric conversion element, and
the pixel separator is a barrier having a length shorter than a length in a height direction of the photoelectric conversion element.

15. The imaging element according to claim 1, wherein
a predetermined number of the light receiving sections constitute a pixel block, and
the imaging element further comprises an overflow drain layer for a predetermined number of the light receiving sections in the pixel block.

16. The imaging element according to claim 1, wherein
a predetermined number of the light receiving sections constitute a pixel block, and
the event detecting section and the pixel signal generating section are provided for each of the pixel blocks.

17. The imaging element according to claim 1, wherein
a predetermined number of the light receiving sections constitute a pixel block, and
the event detecting section adds the charges individually obtained from a predetermined number of the light receiving sections in the pixel block, and generates the event detection signal on a basis of the added charges.

18. The imaging element according to claim 1, wherein
in a case where the event detection signal is generated by the event detecting section, the pixel signal generating section generates the pixel signal on a basis of the charge supplied from the light receiving section.

19. An imaging device, comprising:
an imaging lens; and
an imaging element, wherein
the imaging element includes
a light receiving section that includes a photoelectric conversion element that generates a charge,
an event detecting section that generates an event detection signal on a basis of the charge supplied from the light receiving section,
a pixel signal generating section that generates a pixel signal on a basis of the charge supplied from the light receiving section, and
a switching element that switches between a first electric path through which the charge is supplied from the light receiving section to the event detecting section and a second electric path through which the charge is supplied from the light receiving section to the pixel signal generating section.

20. A method for controlling an imaging element, the method comprising:
by a switching element, switching between a first electric path through which a charge is supplied from a light receiving section including a photoelectric conversion element that generates the charge to an event detecting section that generates an event detection signal on a basis of the charge, and a second electric path through which the charge is supplied from the light receiving section to a pixel signal generating section that generates a pixel signal on a basis of the charge.
